(19) United States
(12) Patent Application Publication
(10) Pub. No.: US 2025/0218720 A1
(43) Pub. Date: Jul. 3, 2025

(54) METHOD OF WAFER GROUNDING UTILIZING WAFER EDGE BACKSIDE COATING EXCLUSION AREA

(71) Applicant: ASML Netherlands B.V., Veldhoven (NL)

(72) Inventors: Yinglong LI, San Jose, CA (US); Niels Johannes, Maria BOSCH, Eindhoven (NL); Jef GOOSSENS, Bocholt (BE); Aimin WU, Milpitas, CA (US); Humad ASGHAR, Milpitas, CA (US); Tianming CHEN, San Jose, CA (US); Peter Paul HEMPENIUS, Eindhoven (NL); Xiang KE, San Jose, CA (US); Joan SANS MERCADER, Eindhoven (NL); Zhi ZHANG, San Jose, CA (US); Jan-Gerard Cornelis VAN DER TOORN, Eindhoven (NL)

(73) Assignee: ASML Netherlands B.V., Veldhoven (NL)

(21) Appl. No.: 18/850,497

(22) PCT Filed: Mar. 16, 2023
(86) PCT No.: PCT/EP2023/056749

§ 371 Date: Sep. 24, 2024

Related U.S. Application Data
(60) Provisional application No. 63/323,728, filed on Mar. 25, 2022.
(60) Provisional application No. 63/341,334, filed on May 12, 2022.
(60) Provisional application No. 63/489,643, filed on Mar. 10, 2023.

(51) Int. Cl. H01J 37/20; H01J 37/317; H01L 21/02

(52) U.S. Cl. CPC H01J 37/20; H01J 37/3178; H01L 21/02271; H01J 2237/2007

(57) ABSTRACT

Systems and methods are provided for grounding a wafer in a charged particle beam apparatus. The systems and methods include providing an exclusion area in a backside film on the wafer of sufficient size to allow an electrical connection between the wafer and an electrical contact of the charged particle beam apparatus. The systems and methods include contacting a pin body to a surface of the wafer, the wafer having a coating on the surface, and the pin body comprising a first tip and a second tip each extending from the pin body; wherein the contacting takes place at a first exclusion area of the coating by any one of the first tip, the second tip, or any combination thereof.

### CROSS-REFERENCE TO RELATED APPLICATIONS

This application claims priority of U.S. application 63/323,728 which was filed on 25 Mar. 2022, U.S. application 63/341,334 which was filed on 12 May 2022, U.S. application 63/489,643 which was filed on 10 Mar. 2023 and which are incorporated herein in its entirety by reference.

### FIELD

The description herein relates to the field of semiconductor manufacturing, and more particularly to wafer grounding and biasing that may be useful for semiconductor wafer processing using a charged particle beam apparatus.

### BACKGROUND

A charged particle beam apparatus is able to produce a 2-dimensional image of a wafer substrate by detecting secondary electrons, backscattered electrons, mirror electrons, or other kinds of electrons from the surface of the wafer substrate upon impingement by a charged particle beam generated by the charged particle beam apparatus. Various charged particle beam apparatuses are used on semiconductor wafers in the semiconductor industry for various purposes such as wafer processing (e.g., e-beam direct write lithography system), process monitoring (e.g., critical dimension scanning electron microscope (CD-SEM)), wafer inspection (e.g., e-beam inspection system), defect analysis (e.g., defect review SEM, or DR-SEM and Focused Ion Beam system, or FIB), etc. When such apparatus performs its function, for better imaging, the electrical potential of the wafer substrate may be held at a predetermined value or be biased. This can be achieved by electrically, or more specifically, resistively connecting the target wafer substrate to a programmable DC voltage source (e.g., a wafer bias supply). Electrical connection may be made when the wafer substrate interacts with the charged particle beam, during which excess charges are brought to the wafer substrate. This process can be referred to as wafer biasing.

For wafer biasing, electrical contact from the wafer bias supply to the wafer substrate is conventionally made at the backside of the wafer substrate by using one or more electrical contacts that press against the backside surface of the wafer substrate. The front surface of the wafer is usually inappropriate to place the electrical contact because features are formed on the front surface. Sometimes a wafer has an electrically insulating film located on its backside surface (e.g., a backside film). The backside film can cause difficulty in establishing a reliable electrical connection between the electrical contacts and a conductive surface of the wafer.

### SUMMARY

Embodiments of the present disclosure include systems and methods for wafer grounding using an exclusion area on a wafer backside film. In some embodiments, the exclusion area is a region on the backside surface in which the backside film material is not present. Embodiments of the present disclosure provide a clean contact between an electrical contact (such as a grounding pin) and a conductive surface of a wafer.

Embodiments of the present disclosure include a wafer having an exclusion area of a backside film for grounding the wafer. The exclusion area may be located, e.g., at a periphery of the wafer backside, at a central region, or at an intermediate region between the center and periphery.

Embodiments of the present disclosure include a wafer grounding system having a grounding pin for contacting an exclusion area of a backside film. The grounding pin and exclusion area may be located, e.g., at a periphery of the wafer backside, at a central region, or at an intermediate region between the center and periphery.

Embodiments of the present disclosure include a charged particle beam inspection method for inspecting a wafer having an exclusion area on a backside film. The method may include inspecting the wafer in two different inspection steps with the wafer supported at two different angular orientations in the wafer plane. One or more exclusion areas are configured so that the wafer may be grounded at an exclusion area during both inspection steps.

Embodiments of the present disclosure include systems and methods for manufacturing a wafer having a backside film exclusion area. Various exemplary systems and methods are disclosed for masking or otherwise preventing film formation on a selected area during the process of forming a thick backside film in a processing chamber.

Embodiments of the present disclosure include systems and methods for electrically connecting to a wafer. Systems and methods may include contacting a pin body to a surface of the wafer, the wafer having a coating on the surface, and the pin body comprising a first tip and a second tip each extending from the pin body; wherein the contacting takes place at a first exclusion area of the coating by any one of the first tip, the second tip, or any combination thereof.

Further objects and advantages of the disclosed embodiments will be set forth in part in the following description, and in part will be apparent from the description, or may be learned by practice of the embodiments. Some objects and advantages of the disclosed embodiments may be realized and attained by the elements and combinations set forth in the claims. However, embodiments of the present disclosure are not necessarily required to achieve such exemplary objects or advantages, and some embodiments may not achieve any of the stated objects or advantages.

It is to be understood that both the foregoing general description and the following detailed description are exemplary and explanatory only and are not restrictive of the disclosed embodiments, as may be claimed.

### BRIEF DESCRIPTION OF THE DRAWINGS

FIG. 1 is a schematic diagram illustrating an example electron beam inspection (EBI) system, consistent with embodiments of the present disclosure.

FIG. 2 is a schematic diagram illustrating an example electron beam tool, consistent with embodiments of the present disclosure that may be a part of the example electron beam inspection system of FIG. 1.

FIG. 3 is an illustration of an example system of wafer grounding, consistent with embodiments of the present disclosure.

FIGS. 4A-4D illustrate operation stages of an example system for wafer grounding in a comparative embodiment.

FIG. 5 is an illustration of a potential issue caused by holes in a wafer backside-film.

FIGS. 6A-C are illustrations of an example subsystem for wafer grounding consistent with embodiments of the present disclosure.

FIG. 6D illustrates an example relationship between exclusion area radial positions, size and rotational positioning accuracy, consistent with embodiments of the present disclosure.

FIGS. 7A-B are illustrations of an example subsystem for wafer grounding consistent with embodiments of the present disclosure.

FIGS. 8A-B are illustrations of an example subsystem for wafer grounding consistent with embodiments of the present disclosure.

FIGS. 9A-B are illustrations of an example subsystem for wafer grounding consistent with embodiments of the present disclosure.

FIG. 10 is an illustration of example wafers having backside film exclusion areas consistent with embodiments of the present disclosure.

FIG. 11A is an illustration of an example backside film formation chamber in a comparative embodiment of the present disclosure.

FIG. 11B is an illustration of an example wafer backside film that may be formed in the chamber of FIG. 11A in a comparative embodiment of the present disclosure.

FIG. 12A is an illustration of an example backside film formation chamber consistent with embodiments of the present disclosure.

FIG. 12B is an illustration of an example wafer backside film that may be formed in the chamber of FIG. 12A consistent with embodiments of the present disclosure.

FIG. 12C is an illustration of an example backside film formation chamber consistent with embodiments of the present disclosure

FIG. 13A is an illustration of an example backside film formation chamber in a comparative embodiment of the present disclosure.

FIG. 13B is an illustration of an example wafer backside film that may be formed in the chamber of FIG. 13A in a comparative embodiment of the present disclosure.

FIG. 14A is an illustration of an example backside film formation chamber consistent with embodiments of the present disclosure.

FIG. 14B is an illustration of an example wafer backside film that may be formed in the chamber of FIG. 14A consistent with embodiments of the present disclosure.

FIG. 15 is a flowchart illustrating an example method for forming a wafer backside film, consistent with embodiments of the present disclosure.

FIG. 16 is a flowchart illustrating an example method for grounding a wafer having a backside film, consistent with embodiments of the present disclosure.

FIG. 17 shows an exemplary exclusion area of a wafer with positions of a single tip grounding pin.

FIG. 18 shows an exemplary exclusion area of a wafer with position of a dual tip grounding pin, consistent with embodiments of the present disclosure.

FIG. 19 shows exemplary exclusion areas of a wafer with positions of a dual tip grounding pin, consistent with embodiments of the present disclosure.

FIG. 20 shows an exemplary wafer with a backside film in contact with a dual tip grounding pin, consistent with embodiments of the present disclosure.

FIG. 21 shows a cross-sectional view of an exemplary dual tip grounding pin, consistent with embodiments of the present disclosure.

FIG. 22 shows an exemplary wafer holder with a grounding pin, consistent with embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SEM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Typically, the structures are made on a substrate (e.g., a silicon wafer) that is placed on a platform, referred to as a stage, for imaging. When the electron beams hit the structures, they may charge the substrate and make the substrate no longer electrically neutral. The charged substrate may obtain a voltage and affect the exiting electrons, which may affect the imaging quality. Accordingly, to improve imaging, it may be advantageous to ground the substrate.

For grounding, the substrate may be electrically connected to an electric power source. The electrical connection between the power source and the substrate may be implemented by pressing one or more conductive grounding pins or probes against the backside surface of the substrate (i.e., the surface without the IC structures). The backside surface of the substrate may be covered by a thin layer (“backside film”) of material.

However, the backside film is not conductive. Various types of methods may be used to overcome such a non-conductive backside film and make an electrical connection. Examples include: (1) an electric zapping method; (2) a penetration method; and (3) a pin-impact method.

In the electric zapping method, the grounding pins may press into and partially penetrate, but not completely penetrate, the backside film. The power source may generate a high-voltage (e.g., tens of kilovolts) electric signal (“zapping signal”) between the grounding pins for the purpose of breaking down the backside film to establish an electrical connection between the grounding pins and the wafer. The zapping signal may cause electric zapping between the grounding pins and the wafer, resulting in a breakdown of the backside film.

In the penetration method, the grounding pins may be pressed into the substrate to penetrate the backside film and contact the substrate directly. But the penetration method may result in damage to the backside film, which can lead to damaging the substrate during manufacturing. It can also lead to excessive particle generation, leading to contamination of the vacuum chamber of the SEM. Furthermore, as discussed below, neither the penetration nor zapping method may overcome all types of backside film.

Some wafers require a thicker backside film than others. For example, some complex IC structures may include a large number of layers. Such multi-layer structures may cause higher tension on the surface of the wafer than in other cases. The high tension may warp or bow the wafer, which may cause errors in the inspection image (e.g., fuzziness). To avoid warping or bowing the wafer due to such complex structures, the wafer may be coated with a thickened backside film to enhance its mechanical strength. However, when a backside film is made sufficiently thick to prevent wafer warping or bowing, it may be too thick for either the electrical zapping method or a conventional penetration method to achieve acceptable wafer grounding.

To overcome the thick-film wafer problem, the “pin-impact” method has been proposed. Rather than simply pressing a pin into the backside film as in a penetration method, the wafer grounding system may actuate a grounding pin to generate a high impact and “punch” the thickened backside film. After penetrating the thickened backside film by impact, an electrical connection between the grounding pin and a conductive surface of the wafer may be established for wafer grounding. However, some backside films are so thick that the force required for a pin-impact method can cause damage to the wafer. Deformation resulting from impact may cause overlay errors and generate contaminant particles in the wafer environment. Furthermore, even with a successful punch, it may be difficult to maintain conductivity in the grounding connection.

Embodiments of the present disclosure include systems and methods for wafer grounding using an exclusion area of the backside film. The exclusion area may be a region on the backside surface in which the backside film is not present, or is thinned or otherwise modified (e.g., using a material of a different conductivity). Embodiments of the present disclosure provide a clean contact between a grounding pin and a conductive surface of a wafer while reducing the risk of particle contamination and deformation-based overlay errors. Further, duration and stability of the electrical connection may be improved.

Embodiments of the present disclosure allow greater design flexibility of a wafer grounding system. For instance, an exclusion area may be located at a periphery of a wafer, and at least some wafer grounding pins may be advantageously moved away from a central region of the wafer. In some embodiments, the wafer may include a plurality of exclusion areas around the periphery to enable SEM inspection under multiple angular orientations of the wafer. In some embodiments, the wafer may include a single annular-shaped exclusion area around the wafer periphery. This enables SEM inspection with a continuously variable set of angular orientations to choose from.

Further embodiments of the present disclosure include a wafer having a backside film exclusion area, as well as systems and methods for manufacturing the wafer having the backside film exclusion area. Various exemplary systems and methods are disclosed for masking, modifying, or preventing film formation at a selected region during formation of a thick backside film.

In some embodiments, the backside film is formed over an entire surface of the wafer, and a portion of the film in an exclusion area is removed during a subsequent processing step. In some embodiments, the exclusion area includes a conductive film having the same or similar thickness as the non-conductive backside film so as to achieve good electrical contact with a high degree of planarity on the wafer backside surface.

Grounding pins may have a single tip to contact an exclusion area of the wafer. Because exclusion areas of a wafer may be small, the position accuracy of a single tip grounding pin contacting an exclusion area may be low. In some embodiments, to improve the position accuracy of grounding pins contacting an exclusion area of the wafer, each grounding pin may include a pin body with two tips extending from the pin body (a “dual tip” grounding pin). The distance between the first tip and the second tip of a grounding pin may be substantially equal to a width of an exclusion area of a wafer to improve the position accuracy of the grounding pin contacting the exclusion area of the wafer. The dual tip grounding pin may be flexibly adjusted such that the chance of the grounding pin contacting an exclusion area of the wafer increases (i.e., the dual tip grounding pin may increase position accuracy).

In some embodiments, a grounding pin may include a spring structure in a wafer holder, where the spring structure may be configured to reduce wafer warp or wafer bow by reducing forces on the wafer.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

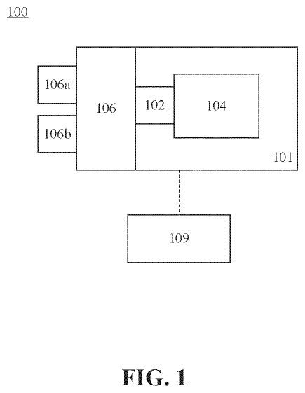

FIG. 1 illustrates an exemplary electron beam inspection (EBI) system 100 consistent with embodiments of the present disclosure. EBI system 100 may be used for imaging or otherwise processing a wafer. The wafer may be grounded. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

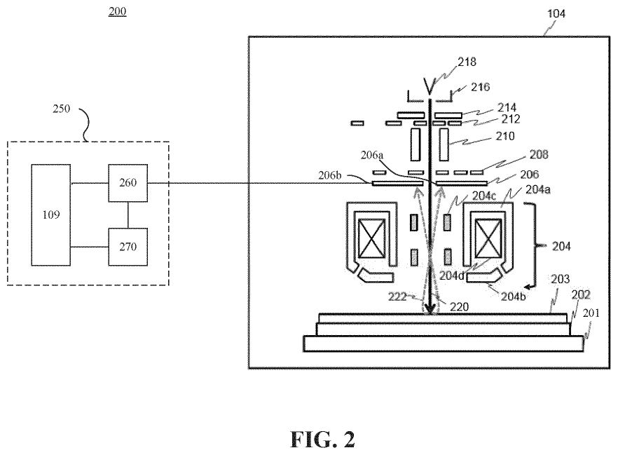

FIG. 2 illustrates an example imaging system 200 according to embodiments of the present disclosure. Electron beam tool 104 of FIG. 2 may be configured for use in EBI system 100 discussed above with reference to FIG. 1. Electron beam tool 104 may be a single beam apparatus or a multi-beam apparatus. As shown in FIG. 2, electron beam tool 104 includes a motorized sample stage 201, and a wafer holder 202 supported by motorized sample stage 201 to hold a wafer 203 to be inspected. Electron beam tool 104 further includes an objective lens assembly 204, an electron detector 206, an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 104 may additionally include an Energy Dispersive X-ray Spectrometer (EDS) detector (not shown) to characterize the materials on wafer 203.

A primary electron beam 220 is emitted from cathode 218 by applying an acceleration voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may generate multiple primary electron beams 220, and electron beam tool 104 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arcing of wafer 203 and to ensure proper beam focus.

A secondary electron beam 222 may be emitted from the part of wafer 203 upon receiving primary electron beam 220. Secondary electron beam 222 may form a beam spot on sensor surfaces of electron detector 206. Electron detector 206 may generate a signal (e.g., a voltage, a current, or the like.) that represents an intensity of the beam spot and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes an electron beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of electron beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or the like. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

Wafer grounding may be implemented by conducting charges from wafer 203 to wafer holder 202 to cause wafer 203 to be electrically neutral. In a comparative grounding system, a penetration method or an electrical zapping method may be used to perform wafer grounding. In those methods, a wafer may be placed on a wafer stage, with its backside supported by the wafer stage. A coating (e.g., a backside film applied to the back of the wafer) may be present on the surface of the backside of the wafer substrate. The backside film may be non-conductive. Two or more grounding pins, made of conductive materials (e.g., metals), may press against the backside film without completely piercing it.

In an electrical zapping method, electric current may enter the wafer from a first grounding pin through the backside film via a first dielectric breakdown and exit the wafer through the backside film to a second grounding pin via a second dielectric breakdown. The dielectric breakdowns may cause a stable electric path (e.g., a direct current (DC) path) to form through the backside film, which may be referred to as a “bias path.” The bias path may have an effective resistance. For example, the resistance of the backside film may contribute to an effective resistance representing resistance of the bias path from the first grounding pin, through the wafer, and to the second grounding pin.

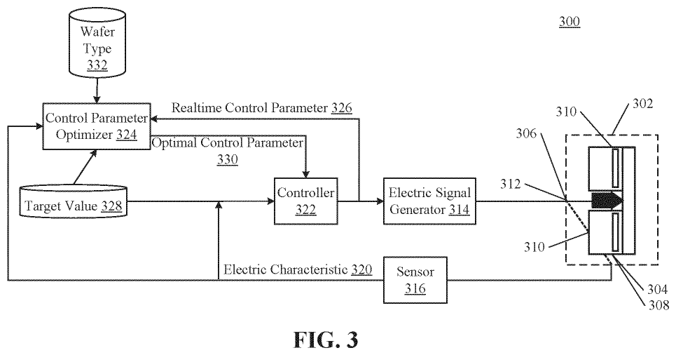

FIG. 3 is an illustration of an example of a system 300 of wafer grounding in a comparative embodiment. System 300 includes a subsystem 302 for holding a wafer, an electric signal generator 314, a sensor 316, a controller 322, and a control parameter optimizer 324.

Subsystem 302 includes an electrostatic holder 306 and wafer 304. In some embodiments, wafer 304 is similar to or the same as wafer 203 in FIG. 2, and electrostatic holder 306 is similar to or the same as wafer holder 202 in FIG. 2. Wafer 304 includes a backside film 308. Backside film 308 may be non-conductive. Electrostatic holder 306 may include at least one electrode 310. When electrified, electrode 310 may attract and secure wafer 304 to electrostatic holder 306 via an electrostatic field. Subsystem 302 further includes at least one grounding pin (or “probe”) 312. Grounding pin 312 may be electrically connected between electric signal generator 314 and wafer 304. In some embodiments, grounding pin 312 may be pressed against backside film 308 without completely penetrating backside film 308. Grounding pin 312 may be electrically connected to electric signal generator 314 and sensor 316.

Electric signal generator 314 may generate a zapping signal for grounding wafer 304. In some embodiments, electric signal generator 314 is a driver. The zapping signal may have a high voltage for causing dielectric breakdown between grounding pin 312 and wafer 304 through backside film 308. Sensor 316 may be used to detect or measure an electric characteristic 320 associated with the electric breakdowns. For example, electric characteristic 320 may include at least one of an impedance, a resistance, a capacitive reactance, an admittance, an emissivity, a conductance, a capacitive susceptance, or any parameter indicating a property of the wafer. In some embodiments, electric characteristic 320 may be associated with an electric path including the grounding pin and the wafer. For example, subsystem 302 may be a single-pin system, which includes a single grounding pin 312. In the single-pin system, sensor 316 may be electrically connected to wafer 304, and may measure electric characteristic 320 representing an electric breakdown between grounding pin 312 and wafer 304 through backside film 308. Further details of the system of FIG. 3 can be found in International Pub. No. WO2021/037827, the entirety of which is incorporated herein by reference.

In some embodiments, highly complex structures are to be manufactured on a wafer. Such complex structures may include a large number of layers. For example, the complex structures may include a three-dimensional circuit that includes one or more NOT-AND (“NAND”) gates, such as a NAND flash memory circuit. Compared with other structures, the multi-layer complex structure may cause higher tension on the surface of the wafer, which may warp or bow the wafer. The bowed wafer may cause problems in the inspection process, such that parts of the wafer may deviate from a focal plane of a primary electron beam (e.g., primary electron beam 220 in FIG. 2). Those problems may cause quality deterioration (e.g., out of focus, blurring, distortion, or the like) of the inspection image.

To avoid warping or bowing the wafer due to such complex structures, in some embodiments, the wafer may be coated with a thickened backside film to enhance its mechanical strength. The backside film may be thickened by 2×, 5×, or 10× or more. For example, in some comparative cases, thickness of the backside film may be 0.1-0.3 μm. To avoid warping or bowing the wafer, the thickness of the backside film may be increased (e.g., to 1.4-2.2 μm or more). However, the thickened backside film may be too thick to the extent that neither the electrical zapping method nor the penetration method are effective for wafer grounding. For example, the thickened backside film may be so thick that no dielectric breakdown can break through it in the electrical zapping method. In another example, the thickened backside film may be so thick that no grounding pin may be pressed to penetrate it by the penetration method.

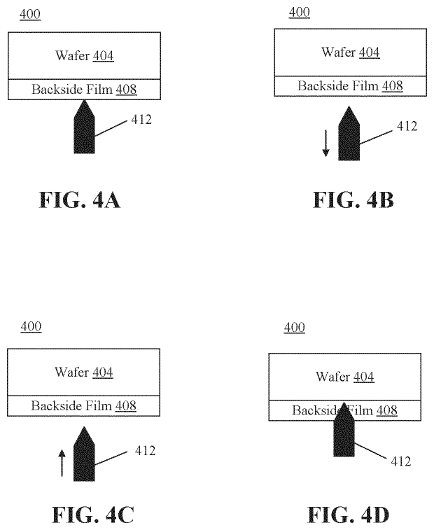

To ground a wafer with a thickened backside film, a “pin-impact method” has been proposed. FIGS. 4A-4D illustrate operation stages of a comparative system 400 for pin-impact wafer grounding. System 400 may be a subsystem of any system for wafer grounding (e.g., system 300 in FIG. 3). Although FIGS. 4A-4D show only one grounding pin, it should be noted that any single-pin system (e.g., subsystem 302 in FIG. 3) or a multi-pin system may be configured to compatibly implement the pin-impact method. For example, in a multi-pin system, the pin-impact method may be compatibly implemented on one or more of its multiple grounding pins.

In FIGS. 4A-4D, system 400 includes wafer 404, backside film 408, grounding pin 412, and an actuator (not shown). Backside film 408 may be the same as or similar to backside film 308 in FIG. 3. In some embodiments, backside film 408 may be thickened. For example, thickness of backside film 408 may exceed 0.3 μm (e.g., 1.4-2.2 μm). In some embodiments, the actuator may include one of an electric actuator (e.g., an electromechanical actuator such as an electric motor, or an electrohydraulic actuator that includes a hydraulic accumulator), a magnetic actuator (e.g., an electric motor), a spring (e.g., a coiled spring or a coiled polymer), a pneumatic actuator, or a hydraulic actuator.

FIG. 4A shows an initial stage of using system 400, in which grounding pin 412 may be controlled (e.g., by controller 322 in FIG. 3) to contact backside film 408. For example, the actuator in the initial stage may be disabled. In other words, grounding pin 412 may be in a default position in the initial stage, in which the default position causes grounding pin 412 to contact backside film 408. Such a configuration of the initial stage may ensure compatibility of system 400 for grounding wafers having no thickened backside film. For example, when a wafer having no thickened backside film is placed in system 400, by setting the initial stage as shown in FIG. 4A, system 400 may perform other methods (e.g., an electrical zapping method or a penetration method) for wafer grounding without invoking the pin-impact method.

FIG. 4B shows a first stage of system 400 implementing the pin-impact method, in which grounding pin 412 is moved away from (as indicated by the arrow) backside film 408 for a distance. In some embodiments, the actuator may move the grounding pin 412 away from the backside film 408. In some embodiments, grounding pin 412 may be moved away from backside film 408 so that the distance between grounding pin 412 (e.g., measured from a tip of grounding pin 412) and backside film 408 may exceed 100 microns. For example, the distance may exceed 1 millimeter. In some embodiments, by moving grounding pin 412 away from backside film 408, grounding pin 412 may have sufficient space for acceleration, as described below.

FIG. 4C shows a second stage of system 400 implementing the pin-impact method, in which the actuator (not shown) may actuate (e.g., accelerate) grounding pin 412 toward backside film 408 (as indicated by the arrow). In some embodiments, the acceleration may end before grounding pin 412 impact backside film 408. In some embodiments, the actuator may actuate grounding pin 412 such that kinetic energy of grounding pin 412 may exceed, for example, 0.0002 joules (e.g., under a maximum travel distance of 3 millimeters for ground pin 412) before impacting backside film 408. It should be noted that the kinetic energy of grounding pin before impacting backside film 408 may depend on its travel distance under the actuation by the actuator, and is not limited to the above examples.

FIG. 4D shows a final stage of system 400 implementing the pin-impact method, in which grounding pin 412 penetrates through backside film 408 by impact due to the kinetic energy gained in the second stage as described in FIG. 4C. In some embodiments, grounding pin 412 may fully penetrate backside film 408 and have a direct contact with wafer 404 without drilling into it. In such cases, an electrical connection between grounding pin 412 and wafer 404 may be established for grounding wafer 404 using a penetration method of wafer grounding. In some embodiments, grounding pin 412 may not fully penetrate backside film 408 such that a distance between a tip of grounding pin 412 and a surface (e.g., a conductive surface) of wafer 404 may be smaller than or equal to 0.3 microns. In such cases, the electrical connection between grounding pin 412 and wafer 404 may be established for grounding wafer 404 using an electric zapping method of wafer grounding. Further details on the pin-impact method may be found in International Pub. No. WO2021/037827.

The pin impact method may not overcome all disadvantages of the prior art. For instance, the destructive action of piercing a thick backside film may introduce particle contamination into the wafer environment. The impact force may deteriorate the grounding pins and reduce their lifetime. It may be difficult to maintain conductivity between the wafer and grounding pin even when the impact is successful. The impact force may additionally cause wafer deformations that may affect overlay performance. The risk of deformation increases with increasing film thickness due to the higher impact energy required to pierce the film. Furthermore, as described below, if a location of the impact hole is not chosen properly, it may introduce additional overlay errors in subsequent processes.

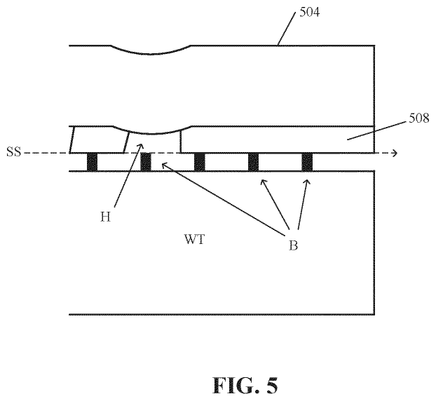

FIG. 5 illustrates an overlay issue in a subsequent process that may result from poor placement of a pin-impact hole. In FIG. 5, a wafer having undergone an inspection process is located on a different wafer support during a subsequent processing stage. For example, the wafer support may be a wafer table WT and the processing stage may be lithographic exposure of a further device layer in a microlithographic exposure apparatus. Wafer 504 is supported at backside film 508 on a plurality of burls B, which are a series of protrusions that form a planar support surface SS. A hole H was created in backside film 508 for grounding wafer 504 during the prior inspection step. If wafer 504 is mounted on wafer table WT such that hole H is located over one of the burls B, the wafer may not be properly supported. This creates a sag that can cause overlay errors in the exposure process.

Embodiments of the present disclosure reflect an improved method for grounding wafers, including wafers with a thick backside film. Rather than punching a large hole into a backside film during setup for an inspection process, an exclusion area is created in the backside film during film formation. Grounding pins may easily make stable electrical contact with a conductive surface of the wafer because there is no film obstructing the contact at a grounding location. Or, there may be a modified film in the exclusion area where it is easier for grounding pins to form electrical contact with the wafer than other parts of the backside film. Advantages of the present disclosure will be illustrated in part with respect to the embodiments discussed herein.

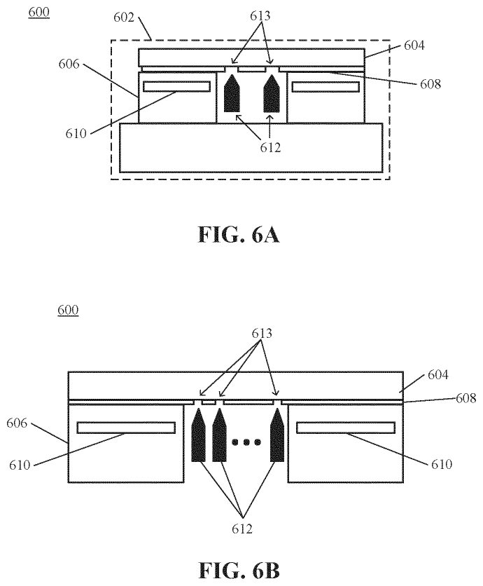

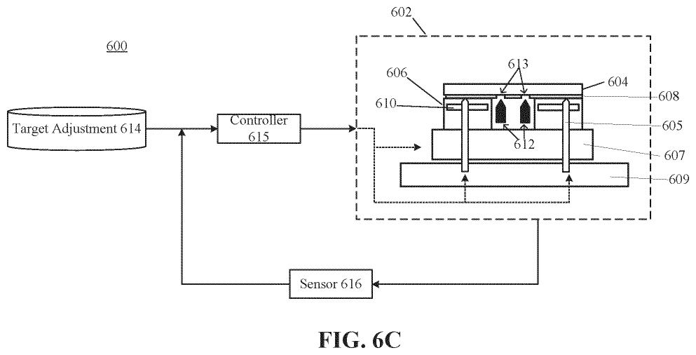

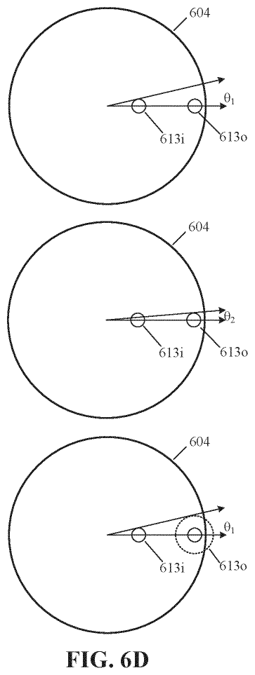

FIG. 6A illustrates a subsystem 600 and wafer 604 consistent with some embodiments of the present disclosure. Subsystem 600 may be a subsystem of any system for wafer grounding (e.g., system 300 in FIG. 3). In FIG. 6A, exclusion areas 613 are formed in backside film 608 and aligned with grounding pins 612. Exclusion areas 613 may be formed as multiple spaced apart areas, as a single contiguous area, or in any geometric configuration. Alternatively or additionally, any of grounding pins 612, wafer 604, holder 606 or sub-components of holder 606, a stage or other supporting components may be moveable by actuators so as to align grounding pins 612 with exclusion areas 613. Backside film 608 may comprise a nonconductive material or a material having a lower conductivity than a material of wafer 604. For example, a backside film may comprise silicon dioxide and a wafer may comprise silicon. The film may be, e.g., silicon nitride, other oxides, nitrides, carbides, or other suitable film materials for providing structural support, e.g., to prevent wafer bow or warp. Exclusion area 613 may be a portion of the layer of backside film 608 in which film material is missing or modified. The missing portion exposes a conductive surface of wafer 604 to a grounding pin 612. However, in some embodiments the backside film material may not be completely missing from some or all of exclusion areas 613. In some embodiments, the backside film 608 is merely made thinner than surrounding portions to allow grounding by any wafer grounding method such as a penetration method, a zapping method or a pin-impact method.

Although FIG. 6A shows two grounding pins, it should be noted that a single-pin system (e.g., subsystem 302 in FIG. 3) or a multi-pin system may be configured to compatibly implement the exclusion area method. For example, in a multi-pin system as seen in FIG. 6B, an exclusion area may be formed for each location of its multiple grounding pins, or for a subset of locations of its multiple grounding pins. There may be more or less exclusion areas than grounding pins. It should be understood that other variants are consistent with some embodiments of the present invention. For example, there may be a single one or a plurality of grounding pins 612. There may be a single one or a plurality of exclusion areas 613. A number of pins 612 may be less than, more than, or equal to a number of exclusion areas 613. One or more of grounding pins 612 may be configured to perform any of an exclusion grounding method, a penetration method, a zapping method, a pin-impact method, or any other suitable wafer grounding method or combinations of wafer grounding methods. Grounding pins 612 and holder 606 may be compatible with a variety of wafers, including thin and thick backside film wafers, wafers with exclusion areas and wafers with no exclusion areas.

FIG. 6C is an illustration of an example system 600 of wafer grounding location adjustment, consistent with embodiments of the present disclosure. It is noted that while FIG. 6C discloses a configuration in the beam tool 104 of main chamber 101, the disclosure is not limited to this arrangement, and not all depicted components will be present in all possible embodiments. In some embodiments, system 600 may be located in a main chamber 101, such as a load-lock chamber 102 or beam tool 104. But in general, system 600 may be applied to any system or module in which a wafer 604 is supported during a process step. System 600 may include a subsystem 602 configured to a wafer 604, a controller 615, a sensor 616, a target adjustment 614. Subsystem 602 may be similar to subsystem 302 in FIG. 3 or subsystem 602 in FIGS. 6A-B, and may include wafer 604, holder 606, backside film 608, electrodes 610, grounding pins 612, a top portion 607 of a wafer stage, a bottom portion 609 of the wafer stage, and actuators including lifters 608.

Sensor 616 may measure a position or orientation of wafer 604. Alternatively or additionally, sensor 616 may measure a position or orientation of exclusion areas 613. The positions or orientations may be in relation to grounding pins 612, holder 606, stage top portion 607, stage lower portion 609, or another reference position or orientation. Sensor 616 may be located above, below or adjacent to wafer 604. Sensor 616 may be embedded within, or mounted upon, holder 606, stage top portion 607, stage lower portion 609 or any other structural component that enables the sensor to determine a desired parameter. Sensor 616 may be configured to access a backside surface of wafer 604 by a hole or other opening in an intervening component. For example, sensor 616 may be located on a stage top portion 607 and be configured to view wafer 604 via an opening in holder 606. Sensor 616 may be configured to detect a reference feature such as an alignment notch or flat, a wafer edge, a fiducial mark, etc. For example, sensor 616 may comprise a laser or other radiation source located above or below the wafer, and a camera such as CCD, CMOS, or other detection device configured to detect the radiation. Sensor 616 may comprise, e.g., an alignment or pre-alignment measurement unit configured to detect an alignment feature. Sensor 616 may be configured as a z-height sensor or other profilometer for identifying an exclusion area 613 by the wafer backside topography that results from a change in backside film thickness. In general, sensor 616 may be optical, capacitive, ultrasonic, or any other configuration for achieving the desired detection. For example, sensor 616 may use imaging, time of flight, interferometry, ellipsometry, capacitance, ultrasound, or any other detection system for determining an exclusion area or a reference location.

In some embodiments, target adjustment 614 may include values of parameters to be used by controller 615 for controlling the actuators of subsystem 602 to align grounding pin 612 locations with target locations. For example, the target locations may include a location of an exclusion area 613. In some embodiments, data for target adjustment 614 may be stored in a database (e.g., in the one or more memories of system 100 in FIG. 1). The actuators may include electric actuators, magnetic actuators, electromagnetic actuators, hydraulic actuators, mechanical actuators, or any suitable type of actuators. In some embodiments, the wafer stage (including top portion 607 and bottom portion 609) may be motorized sample stage 201 in FIG. 2.

Controller 615 may be electrically connected to sensor 616 and the actuators, including lifters 608 and actuators (not shown) mechanically connected to top portion 607. Controller 615 may control the actuators to move various parts of subsystem 602, such as lifters 608, top portion 607, grounding pins 612, or other mechanical components (e.g., a robot arm) for moving wafer 604. For example, the dashed arrow between controller 615 and top portion 607 may indicate that controller 615 may control actuators (not shown) to move top portion 607 horizontally, vertically, or both. The dashed arrow between controller 615 and lifters 608 may indicate that controller 615 may control lifters 608 to move wafer 604 vertically. In some embodiments, controller 615 may further connect to a database to retrieve parameters for controlling the actuators or store data received from sensor 616. For example, controller 615 may access the database storing target adjustment 614. In some embodiments, controller 615 may be implemented as part of controller 109 in FIGS. 1-2. In some embodiments, controller 615 may be implemented as a controller independent from controller 109, such as a software module or a hardware module.

In some embodiments, bottom portion 609 may be stationary, and top portion 607 may be movable. For example, top portion 607 may be movable (e.g., along the vertical direction, the horizontal direction, or both) or rotatable in the horizontal direction, or both. In some embodiments, holder 606 may be fixed to top portion 607 and may also be movable therewith. In some embodiments, top portion 607 may support wafer 604 via holder 606 and fix grounding pins 612. For example, an end of a grounding pin may be fixed to top portion 607 and may also be movable with top portion 607. When wafer 604 rests on top portion 607 (e.g., on top of holder 606), grounding pins 612 may contact a bottom surface (e.g., backside film 608) of wafer 604.

In some embodiments, the actuators may move the top portion. For example, the actuators may include a rotational mechanism (not shown) to rotate top portion 607 in the horizontal direction, such as by an azimuthal angle. In some embodiments, the actuators may include lifters 608. A first end of a lifter may be fixed to bottom portion 609, and a second end of a lifter may be vertically movable. For example, the first end of the lifter may be horizontally fixed to the bottom portion 609 (e.g., by penetrating a hole in the bottom portion 609) and vertically movable. The second end of the lifter may be raised or lowered by a moving mechanism, such as an electromagnetic actuator or a hydraulic actuator. The second end of the lifter may penetrate through top portion 607, holder 606, and electrodes 610, such as by penetrating holes or grooves therein. The second end of the lifter may move beyond a top surface of the holder 606 and contact the bottom surface of wafer 604. In subsystem 602, by raising the lifters to a certain height (e.g., several millimeters), wafer 604 may be raised to leave the top surface of the holder 606 and be detached with grounding pins 612.

In some embodiments, lifters 608 may be vertically and horizontally fixed, and top portion 607 may be vertically movable. When top portion 607 is lowered, grounding pins 612 and holder 606 may be lowered as well. However, lifters 608 may support wafer 604, and wafer 604 may be vertically stationary. By lowering top portion 607, holder 606 may be lowered to leave the bottom surface of wafer 604, and grounding pins 612 may be detached with the bottom surface.

In some embodiments for wafer grounding location adjustment, a wafer may be loaded in a predetermined position or orientation based on a determined location of an exclusion area. For example, a visual inspection, pre-alignment detection or other sensing operation may be used to determine a reference feature, such as an alignment notch or flat. An exclusion area location may then be determined by a known relationship between the reference feature and the exclusion area. Alternatively or additionally, a sensor may be used to directly determine an exclusion area location. In some embodiments, a sensor 616 as described above may be used to determine the location of an exclusion area or reference feature. Based on a determined location of the exclusion area, the wafer may then be loaded in the proper position or orientation so that a grounding pin 612 aligns with a desired exclusion area 613.

In some embodiments, controller 615 may adjust a relative displacement between grounding pins 612 and exclusion areas 613 based on a determined positional error between them. For example, controller 615 may control sensor 616 to measure a parameter indicating a relative position or orientation of grounding pins 612 and exclusion areas 613. Controller 615 may further retrieve target adjustment 614 (e.g., a value of a target position or rotational angle). Controller 615 may compare the target position or angle with the current position or angle, such as by determining a difference therebetween. Controller 615 may then control the various actuators discussed above for adjusting the grounding locations. In some embodiments, controller 615 may store computer-readable instructions in an accessible memory, such as a software module, and execute such instructions to perform the aforementioned operations. Further actuation details may be found in the above-incorporated International Pub. No. WO2021/037827, which is incorporated herein by entirety.

Exclusion areas 613 may be sized to allow easy and stable electrical contact between grounding pins 612 and wafer 604. Exclusion areas 613 may have a size that is expressed as a proportion of total area of wafer 604, or may be relative to grounding pins 612 or other elements. For example, each of exclusion areas 613 may have a size that is at least as large as a cross-sectional contact area of each of grounding pins 612. Exclusion areas 613 may have a size that is large enough to account for alignment error between a grounding pin and a centroid of an exclusion area. In some embodiments, each of exclusion areas 613 may have an area of at least 1, 1.5, 2, 3, 5, 10 or 20 times the cross-sectional contact area of corresponding grounding pins 612. Exclusion areas may be, e.g., between 0.04 and 0.06 mm² or more. In some embodiments, each of exclusion areas 613 may have an area of at least 0.01, 0.1, 0.5, 1, 1.5, 2, 3 or 5 mm² or more.

In some embodiments, a dimension of an exclusion area may be designed in accordance with a predetermined positioning accuracy of a grounding pin relative to the exclusion area. For example, if a positioning accuracy of the center of a grounding pin relative to the center of an exclusion area were +/−90 μm, then the exclusion area dimension could equal the width of the grounding pin plus 180 μm. Alternatively, a larger tolerance could be added to account for unforeseen errors or other issues. For example, an exclusion area dimension having the same conditions above could be designed for a positioning tolerance of, e.g., +/−250 μm. In this case the exclusion area dimension could equal the width of the grounding pin plus 500 μm.

Exclusion area dimensions may also depend on a radial position on the wafer due to limitations on rotational positioning accuracy. As seen in FIG. 6D, the underside of wafer 604 has two circular exclusion areas: an inner exclusion area 613i located near the center of wafer 604, and an outer exclusion area 613o located near the periphery. For a given exclusion area size, an angular range θ₁ of inner exclusion area 613i will be larger than an angular range θ₂ of outer exclusion area 613o. Therefore, as an exclusion area location moves closer to a wafer edge, it may be subject to tighter positioning tolerances (as seen in the middle of FIG. 6D) or increased size (as seen at bottom in dashed lines) in the circumferential direction. Yet because the exclusion areas may be created during a film formation process, there is a great deal of design flexibility that beneficially allows for the use of peripheral exclusion areas.

In some embodiments, the exclusion area may have a size in a first direction that is different from a size in a second direction. For example, a first direction may be a radial direction on a wafer surface, and a second direction may be a circumferential direction on the wafer surface. The size in the first direction may be at least at least 0.1, 0.5, 1, 1.5, 2, 3 or 5 mm or more. The size in the second direction may be larger than the size in the first direction. In some embodiments, the size in the second direction may be 2, 5, 10 or 50 times the size in the first direction or more. The size in the second direction may encircle the entire wafer. Alternatively, the size in the second direction may be the same as, or smaller than, the size in the first direction.

In some embodiments, a grounding pin may have a pointed, elongated or domed geometry, among others. In some embodiments, the additional degrees of freedom afforded by a custom exclusion area may allow for different pin sizes or geometries than those presently in use. For example, an exclusion area may be made large enough to accommodate larger grounding pins for increased contact area, stability or durability. Additionally, a grounding pin may have different geometries, e.g. a blunted tip or a flat pillar shape, in order to increase a contact surface area between the pin and wafer while achieving a mechanically stable connection.

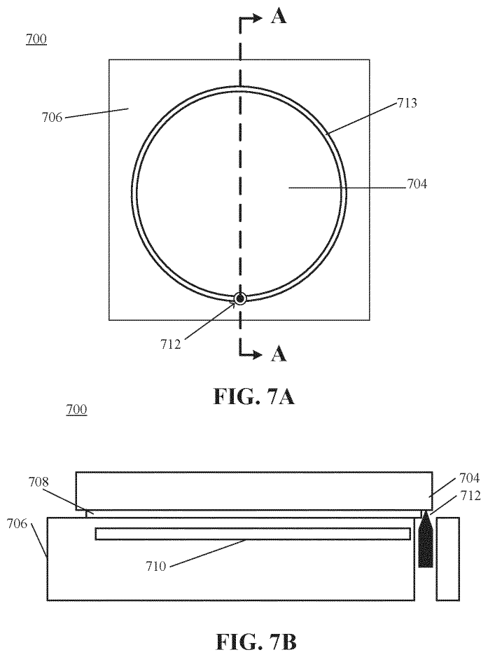

FIGS. 7A-B illustrate a subsystem 700 and wafer 704 consistent with some embodiments of the present disclosure. Subsystem 700 may be a subsystem of any system for wafer grounding (e.g., system 300 in FIG. 3). FIG. 7A diagrammatically shows a backside of wafer 704 in subsystem 700. A holder 706 supports wafer 704 and contacts a backside film 708 of wafer 704. Holder 706 can be an electrostatic holder that includes at least one electrode 710. Grounding pin 712 is located at a peripheral region. The peripheral region may be at the periphery of wafer 704. Exclusion area 713 is annular and encircles wafer 704 at its periphery. In this arrangement, exclusion area 713 may avoid an overlay issue, for example if the exclusion area 713 is located outside a burl region of the wafer table or holder 706. For example, as described above with respect to FIG. 5, there may be plurality of burls B protruding from wafer table WT that form a planar support surface, and there could be a chance that a hole H is created in the backside film for grounding the wafer in the region of the burls if no exclusion area is provided. Alternatively, even if the annular exclusion area is located over burls, any resultant wafer sag may be more symmetrical and may thus be easier to compensate. In some embodiments, locating a grounding pin 712 at the periphery of wafer 704 may also provide greater flexibility or simplicity in the design of holder 706 and electrode 710.

FIG. 7B shows a cross section of subsystem 700 along cut line A-A of FIG. 7A. Grounding pin 712 is able to make direct electrical contact with a conductive surface of wafer 704 at whatever portion of annular exclusion area 713 that is placed above it. In this way, an annular shaped exclusion area 713 allows greater flexibility. Wafer 704 may be rotated as needed for, e.g., alignment purposes, and then wafer 704 may be grounded by deploying grounding pin 712. For example, in some embodiments it may be desirable to scan an electron beam in a specific direction relative to the device features of a wafer under inspection or undergoing lithography. It may be desirable to mount the wafer with a chosen angular orientation within the plane of the page in FIG. 7A. In some embodiments it may be desirable to scan a wafer multiple times using a plurality of different angular orientations. In FIGS. 7A-B, grounding pin 712 may contact a conductive surface in exclusion area 713 regardless of the angular orientation in which wafer 704 is mounted.

While the arrangement of FIGS. 7A-B shows a single grounding pin 712 and a continuous exclusion area 713, it should be understood that other variants are consistent with some embodiments of the present disclosure. For example, there may be a plurality of grounding pins 712 or a plurality of discrete exclusion areas 713. A number of grounding pins 712 may be less than, more than, or equal to a number of exclusion areas 713. Grounding pin 712 may be configured to perform any of an exclusion grounding method of the present disclosure, a penetration method, a zapping method, a pin-impact method, or any other suitable wafer grounding method or combinations of wafer grounding methods. Grounding pin 712 and holder 706 may be compatible with a variety of wafers, including thin and thick backside film wafers, wafers with exclusion areas and wafers with no exclusion area.

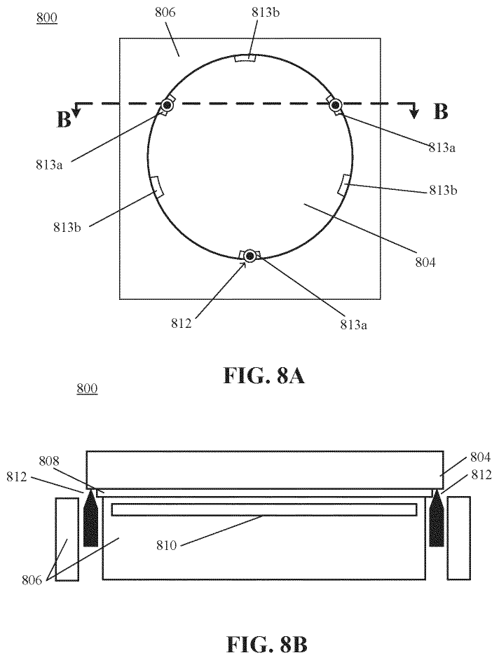

FIGS. 8A-B illustrate a subsystem 800 and wafer 804 consistent with some embodiments of the present disclosure. Subsystem 800 may be a subsystem of any system for wafer grounding (e.g., system 300 in FIG. 3). FIG. 8A diagrammatically shows a backside of wafer 804 in subsystem 800. A holder 806 supports wafer 804 and contacts a backside film 808 of wafer 804. Subsystem 800 comprises a plurality (e.g., three) of grounding pins 812 spaced at equal angular offsets (e.g., at 120° offsets) and arranged to contact a periphery of wafer 804. Wafer 804 comprises a plurality (e.g., six) of exclusion areas 813 at a periphery of wafer 804, spaced at equal angular offsets (e.g., at 60° offsets) corresponding to the offsets of grounding pins 812 or a factor thereof (e.g., 2). Alternatively or additionally, grounding pins 812 may be moveable by actuators so as to be positioned under exclusion areas 813. Wafer 804 may be mounted in a manner such that grounding pins 812 are positioned under a first set of exclusion areas 813a or a second set of exclusion areas 813b. Exclusion areas may have a size in a circumferential direction that is large enough to accommodate angular adjustments of wafer 804.

FIG. 8B shows a cross section of subsystem 800 along cut line B-B of FIG. 8A. Grounding pins 812 are able to make direct electrical contact with a conductive surface of wafer 804 at any exclusion areas 813 positioned above them. In this way, a plurality of exclusion areas 813 allow greater flexibility as discussed with respect to FIGS. 7A-B above.

For instance, a method may include: supporting a wafer on a holder in a first angular orientation; grounding the wafer by contacting a grounding pin to a first exclusion area; performing a first charged particle beam process (such as a first SEM inspection) with the wafer in the first angular orientation; supporting the wafer on the holder in a second angular orientation different from the first angular orientation; grounding the wafer by contacting the grounding pin to a second exclusion area; and performing a second charged particle beam process (such as a second SEM inspection) with the wafer in the second angular orientation. The first and second exclusion areas may be, e.g., first and second portions of a continuous exclusion area (such as 713 as seen in FIG. 7A), or first and second discrete exclusion areas (such as 813a and 813b as seen in FIG. 8A).

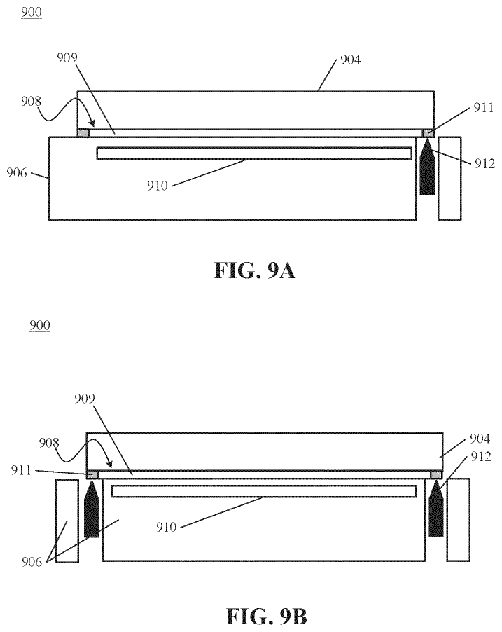

FIGS. 9A-B show further embodiments of subsystems 900 and wafers 904 consistent with some embodiments of the present disclosure. A holder 906 supports wafer 904 and contacts a backside film 908 of wafer 904. In FIGS. 9A-B, an exclusion area comprises a second material 911 having a higher conductivity than a first material 909 of backside film 908. The second material may comprise a conductive material such as aluminum, tungsten, gold, copper or any other metal or conductive material. Second material 911 may partially or completely fill a void in backside film 908. Second material 911 may be substantially coplanar with backside film 908. Second material 911 may serve to add further support against wafer bowing or warping. Second material 911 may increase the backside surface planarity of wafer 904 compared to other embodiments, while still providing a stable electrical connection between grounding pin 912 and wafer 904.

First material 909 and second material 911 of the backside film may have differing properties other than conductivity. For example, second material 911 may have a hardness that is less than that of the first material 909 of backside film 908. Backside film 908 may be configured such that grounding pin 912 can more easily penetrate into second material 911 than the first material 909.

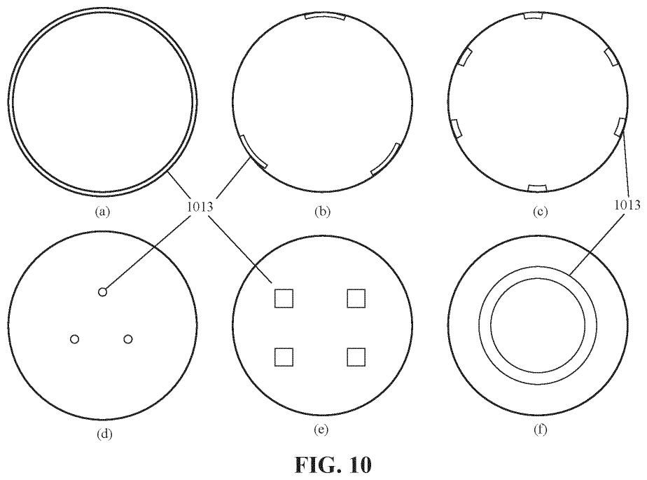

The exclusion area configurations are not limited to those of FIGS. 7-9. FIG. 10 shows, by way of example and without limitation, a plurality of possible exclusion areas on wafers (a)-(f). In general, exclusion areas may vary in number, size, shape, region, or any similar parameter as needed. Exclusion areas may have at least one of an annular shape, an arcuate shape, a rectangular shape, and a circular shape. Exclusion areas may be located in a central, peripheral, or intermediate region, or in a combination of such regions. The exclusion areas may comprise a void in which a backside film material is missing entirely, a region in which a backside film is relatively thinner than a remainder of a backside film layer, or a region containing a second material that has a higher conductivity (or some other property) than a first backside film material. While the arrangements of FIG. 10 are symmetrical, the exclusion areas need not be arranged with rotational or mirror symmetry. In some embodiments, a single exclusion area may be located on a wafer, e.g., at a periphery.

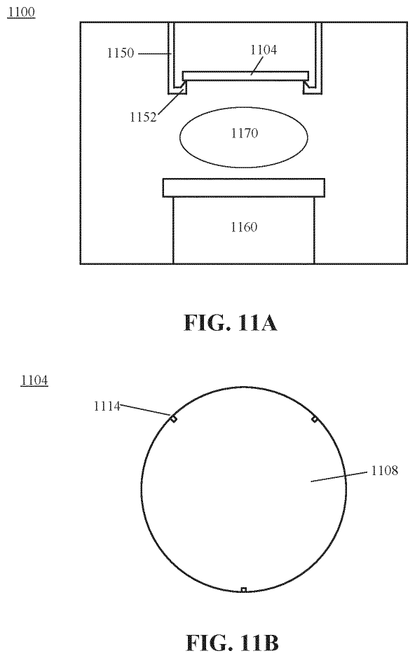

FIG. 11A shows a processing chamber 1100 for forming a backside film on a wafer 1104 in a comparative embodiment. The processing chamber may comprise a suspension unit 1150 for suspending wafer 1104 above a processing unit 1160 to expose a backside of wafer 1104 to processing material 1170 in a process region. Processing material 1170 may include, e.g., a process gas, a target material, a chemical precursor, a plasma, or combinations of such processing materials depending on the nature of the film formation process. Suspension unit 1150 comprises one or more support members 1152 for supporting a backside of wafer 1104 at one or more points. The comparative embodiment is not designed to form an exclusion area for grounding wafer 1104 during a subsequent SEM inspection process or other semiconductor manufacturing process. Support member 1152 has a narrow contact point at the backside of wafer 1104 to suspend wafer 1104 while allowing substantially the entire backside surface to form a backside film 1308.

Processing chamber 1100 may be configured to perform any film formation process known in semiconductor manufacturing. By way of example and without limitation, the film formation process may include Chemical Vapor Deposition (CVD), Plasma Enhanced Chemical Vapor Deposition (PECVD), Low Pressure Chemical Vapor Deposition (LPCVD), High Density Plasma Chemical Vapor Deposition (HDPCVD), Physical Vapor Deposition (PVD), Plasma Enhanced Physical Vapor Deposition (PEPVD), Atomic Layer Deposition (ALD), Plasma Enhanced Atomic Layer Deposition (ALD), sputtering, passivation, or any process for depositing, coating or growing a backside film on wafer 1104. In some embodiments, processing chamber 1100 is a PECVD chamber. Processing unit 1160 may comprise a showerhead electrode electrically connected to a high frequency power source (not shown) and configured to introduce a process gas 1170 comprising precursors of a backside film material. Wafer 1104 is connected to a grounded electrode (not shown). The electrodes and high frequency power source ionize the precursors in process gas 1170 to form a plasma, and some reactants of the plasma are deposited as a backside film 1108.

FIG. 11B shows a backside view of wafer 1104 processed in the processing chamber of FIG. 11A. As shown in FIG. 11B, the wafer backside film 1108 formed in the processing chamber 1100 comprises a plurality of film reduction points 1114. The film reduction points are locations at which formation of backside film 1108 was hindered to a degree by the support member 1152. Film reduction points 1114 may be considered to be partial exclusion areas that are smaller than an ideal size, or that do not leave a conductive surface fully exposed. For instance, a film reduction point may have a size in a radial direction of, e.g., between 0.1-1.5 mm.

The comparative embodiment may be designed for the purpose of preventing film reduction points 1114 as much as possible, and film reduction points 1114 may not fully expose a conductive surface of wafer 1104, or may not expose a sufficient area of the conductive surface for optimal grounding by an exclusion area method. Still, in some embodiments, a grounding method may include contacting film reduction point 1114 with a grounding pin (such as peripheral grounding pins 712-912 of FIGS. 7A-9B). The grounding method may include grounding wafer 1104 using a penetration method, a zapping method, a pin-impact method, or any other suitable wafer grounding method or combinations of wafer grounding methods.

In comparison to the comparative embodiment, an exclusion grounding method may be designed for the purpose of forming an exclusion area to be used in a grounding process. An exclusion grounding method may include determining a location of the exclusion area. Determining a location of the exclusion area may be based on information that is acquired during a determination process or information that is previously known.

Information acquired during a determination process may include, e.g., optical or visual inspection information. For example, a dedicated inspection may be performed to locate an exclusion area on the backside of the wafer. The inspection may be a visual inspection performed by an operator. The inspection may be an optical inspection. The optical inspection may distinguish an exclusion area from its surroundings by detecting differences in optical properties (e.g., reflective, refractive, absorptive, filtering or other properties) on a backside of the wafer relative to ambient or projected light. The inspection may be an optical inspection for distinguishing an exclusion area from its surroundings by detecting differences in optical properties (e.g., reflective, refractive, or filtering properties) of ambient or projected light passing through the wafer. Alternatively, data from another inspection may be utilized to determine a location of an exclusion region. The inspection may determine a location, shape, size or type (e.g., void, thin-film region, alternative material, etc.) of the exclusion area. Information acquired during a determination process may include an electrical inspection. For example, the electrical inspection may utilize sensor 316 to detect or measure an electrical characteristic 320 as discussed above with respect to FIG. 3. Results of measurements of the electrical characteristic at different points on a wafer surface may be used to determine the location, shape, size or type of an exclusion area.

Previously known information may include a location, shape, size or type of the exclusion area as provided by a manufacturer or supplier of the wafer. For example, a center location of the exclusion area may be provided in polar coordinates relative to a reference mark such as a pre-alignment notch. A location may be given in terms of a feature with which it overlaps, e.g., a band surrounding a pre-alignment notch by a certain thickness (e.g., 0.01, 0.1, 0.5, 1, 1.5, 2, 3 or 5 mm), or an annular ring extending radially inward from an edge by a distance (e.g., 0.01, 0.1, 0.5, 1, 1.5, 2, 3 or 5 mm). Previously known information may comprise information acquired as discussed above, wherein the acquired information is acquired from a different wafer.

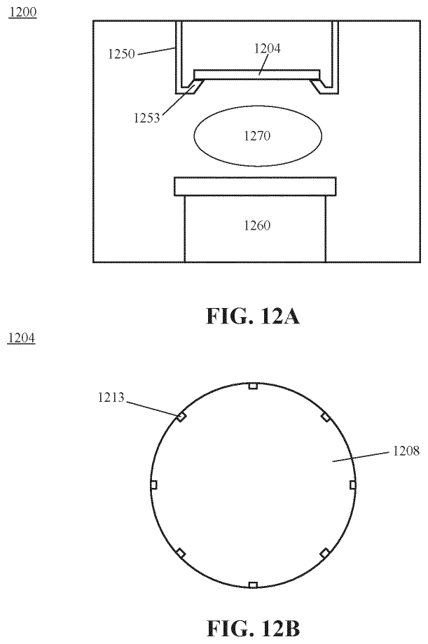

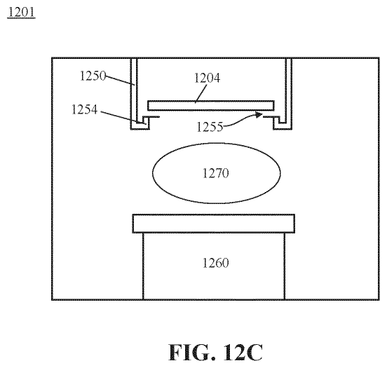

FIG. 12A shows a processing chamber 1200 consistent with some embodiments of the present disclosure. Processing chamber 1200 may be similar to processing chamber 1100 except as described herein. Suspension unit 1250 comprises one or more support members 1253 configured to cover one or more exclusion areas 1213 (see FIG. 12B). Support member 1253 may be configured to support a wafer 1204 during a film formation process. At the same time, support member 1253 may be configured as an exclusion mask having a size and shape configured to prevent film formation at exclusion area 1213. Support member 1253 may have a size, shape and configuration corresponding to any of the exclusion areas disclosed or contemplated herein, including exclusion areas 613, 713, 813, 913 and 1013. For example, the support member 1253 may take the form of an arc shape or an annular shape around a backside surface of wafer 1204, or any other shape as need to create a desired exclusion area.

FIG. 12B shows wafer 1204 formed with exclusion areas consistent with some embodiments of the present disclosure. Wafer 1204 has a backside film 1208 formed in processing chamber 1200. Because support members 1253 were in contact with a backside surface of wafer 1204 at exclusion areas 1213 during formation of backside film 1208, film formation was reduced or eliminated in the exclusion areas 1213. Therefore, a thick backside film can be formed while providing exclusion areas 1213 of any desired number, size, shape, location, and orientation. For example, exclusion areas 1213 may take a form disclosed with respect to FIG. 10 or any other desired form.

FIG. 12C illustrates a processing chamber 1201 consistent with some embodiments of the present invention. The processing chamber 1201 may be, e.g., similar to the processing chamber 1200 of FIG. 12A or the processing chamber 1100 of FIG. 11A except as described below. Suspension unit 1250 includes a proximity-type exclusion mask 1254 near a backside surface of wafer 1204. In some embodiments, exclusion mask 1254 does not contact wafer 1204. In some embodiments exclusion mask 1254 touches wafer 1204 but does not substantially support the weight of wafer 1204. Support is provided by another mechanism, such as one or more support members (not shown). Support members may be the same as or similar to support members 1152 in FIG. 11A or 1253 in FIG. 12A. Alternatively wafer 1204 may be held at its upper surface by a gripping or chucking device. In a non-contact embodiment as seen in FIG. 12C, a gap 1255 may be small enough for exclusion mask 1254 to reduce or eliminate film formation in an exclusion area. The necessary or optimal gap distance may vary depending on the particular film formation method chosen. By way of example and without limitation, in some embodiments a distance of gap 1255 may be between 1-10 μm, between 5-50 μm, between 10-100 μm, between 50 μm-1 mm, or between 500 μm-10 mm. While exclusion mask 1254 is depicted as a rigid object, it may alternatively take any form that reduces or prevents film formation at exclusion area 1213. For example, exclusion mask 1254 may be a removeable film or a treatment applied to wafer 1204 prior to a backside film formation process in processing chambers 1200 or 1201. Alternatively or additionally, exclusion area 1213 may be formed by post-deposition processes such as an etching process. Exclusion areas formed by the chamber of FIG. 12C may have a same or similar design as those discussed above with respect to FIG. 10 and FIG. 12B, or they may take any other desired form.

In addition to the variety of exclusion areas made possible by the present disclosure, a backside film may advantageously be made thicker as well. In comparative embodiments, a film thickness may be limited by the need to ground a wafer by penetration, zapping, or pin-impact. Because the challenge of grounding a wafer through a thick insulating layer is overcome may be overcome, a backside film thickness may be increased. In some embodiments of the present disclosure, a wafer may have a backside film with a thickness of, e.g., 1-2.2 μm, 2-5 μm, 5-10 μm, or 10-50 μm. the increased thickness may provide additional structural rigidity to prevent wafer bow or warp while maintaining stable electrical contact with a conductive surface of the wafer during a wafer grounding process. The increased thickness may also serve to compensate for any loss of rigidity caused by the missing material of exclusion areas. Thus, a thicker backside film may allow for further design flexibility, e.g., greater choice of size and location, for exclusion areas.

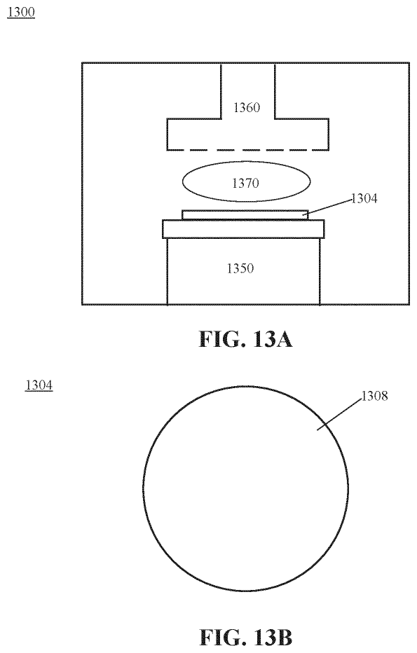

FIG. 13A shows a processing chamber 1300 for forming a backside film on a wafer 1304 in a comparative embodiment. Processing chamber 1300 may comprise a table 1350 for holding wafer 1304 under a processing unit 1360 to expose an upward-facing backside surface of wafer 1304 to processing material 1370. Table 1450 may be, e.g., a susceptor, burl plate, or other device for supporting a wafer from underneath. Table 1350 comprises a support surface for holding wafer 1304 with its backside surface facing upward. The comparative embodiment is not designed to form an exclusion area for grounding wafer 1304 during a subsequent SEM inspection process or other semiconductor manufacturing process. Table 1350 does not substantially obstruct a portion of an upward-facing backside surface of wafer 1304. Therefore, substantially the entire backside surface may be coated with a backside film 1308. The film may be, e.g., silicon dioxide, silicon nitride, other oxides, nitrides, carbides, or other suitable film materials for providing structural support, e.g., to prevent wafer bow or warp.

Processing chamber 1300 may be configured to perform any film formation process known in the semiconductor manufacturing industry. By way of example and without limitation, the film formation process may include Chemical Vapor Deposition (CVD), Plasma Enhanced Chemical Vapor Deposition (PECVD), Low Pressure Chemical Vapor Deposition (LPCVD), High Density Plasma Chemical Vapor Deposition (HDPCVD), Physical Vapor Deposition (PVD), Plasma Enhanced Physical Vapor Deposition (PEPVD), Atomic Layer Deposition (ALD), Plasma Enhanced Atomic Layer Deposition (ALD), sputtering, passivation, or any process for depositing, coating or growing a backside film on wafer 1304. In some embodiments, processing chamber 1300 is a PECVD chamber. Processing unit 1360 may comprise a showerhead electrode electrically connected to a high frequency power source (not shown) and configured to introduce a process gas 1370 comprising precursors of a backside film material. Wafer 1304 is connected to a grounded electrode (not shown). The electrodes and high frequency power source ionize the precursors in process gas 1370 to form a plasma, and some reactants of the plasma are deposited as a backside film 1308

FIG. 13B shows a backside view of wafer 1304 processed in the processing chamber of FIG. 13A. As seen in FIG. 13B, wafer backside film 1308 formed in processing chamber 1300 covers substantially an entire backside surface of wafer 1304. No film reduction points or exclusion areas are present.

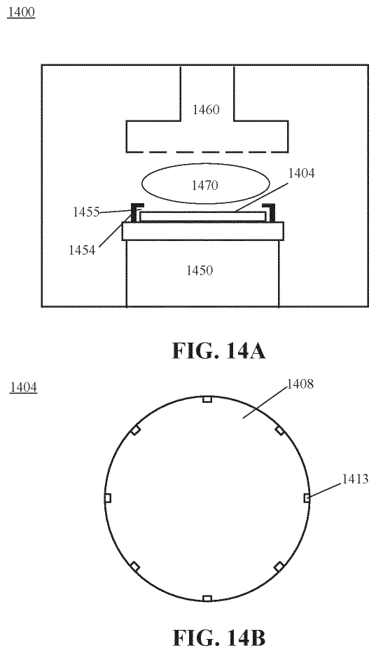

FIG. 14A shows a processing chamber 1400 consistent with some embodiments of the present disclosure. Processing chamber 1400 may be similar to processing chamber 1300 except as described herein. Table 1450 comprises one or more exclusion masks 1454 configured to cover one or more exclusion areas 1413 (see FIG. 14B). Exclusion mask 1454 may have a size, shape and configuration corresponding to any of the exclusion areas disclosed or contemplated herein, including exclusion areas 613, 713, 813, 913 and 1013. For example, exclusion mask 1454 may have an arc shape or an annular shape provided around a backside surface of a wafer 1404, or any other shape as needed to create a desired exclusion area. Exclusion mask 1454 may be mounted on table 1450 or may be placed directly on wafer 1404. The latter is especially advantageous when forming an exclusion area 1413 at a central region of wafer 1404. Exclusion mask 1454 may be in contact with an upward-facing backside surface of wafer 1404, or it may be a proximity-type exclusion mask separated from the surface by a gap 1455. In a non-contact embodiment as seen in FIG. 14A, gap 1455 may be small enough for exclusion mask 1454 to reduce or eliminate film formation in exclusion area 1413. The necessary or optimal gap distance may vary depending on the particular film formation method chosen. By way of example and without limitation, in some embodiments a distance of gap 1455 may be between 1-10 μm, between 5-50 μm, between 10-100 μm, between 50 μm-1 mm, or between 500 μm-10 mm. While exclusion mask 1454 is depicted as a rigid object, it may alternatively take any form that reduces or prevents film formation at exclusion area 1413. For example, exclusion mask 1454 may be a removeable film or other treatment applied to wafer 1404 prior to a backside film formation process in processing chamber 1400. Alternatively or additionally, exclusion area 1413 may be formed by post-deposition processes such as an etching process.

FIG. 14B shows wafer 1404 formed with exclusion areas consistent with some embodiments of the present disclosure. Wafer 1404 has a backside film 1408 formed in processing chamber 1400. Because exclusion masks 1454 are in contact with, or close proximity to, a backside surface of wafer 1404 during formation of backside film 1408, film formation is reduced or eliminated in the exclusion areas 1413. Therefore, a thick backside film can be formed while providing exclusion areas 1413 of any desired number, size, shape, location, and orientation.

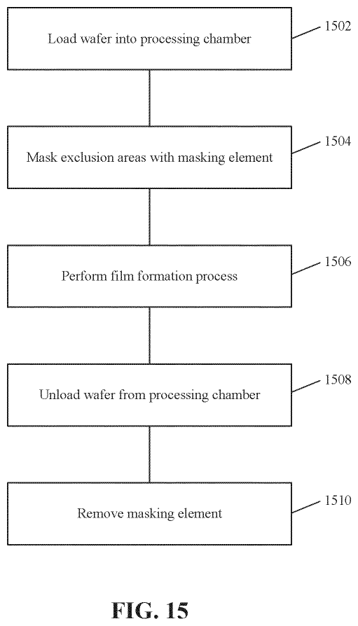

FIG. 15 illustrates a method 1500 for forming a backside film having an exclusion area according to embodiments of the present disclosure. At step 1502, a wafer is loaded into a processing chamber. The processing chamber may be any suitable processing chamber, such as processing chambers 1200, 1201, and 1400 of FIG. 12A, FIG. 12C or FIG. 14A. At step 1504, a region of a wafer is masked with an exclusion mask according to a desired exclusion area as discussed above. The exclusion mask may be any of elements 1253, 1254 or 1454 of FIG. 12A, FIG. 12C or FIG. 14A. The exclusion mask may be a removeable film or other treatment applied to the wafer as discussed above. In some embodiments the step of masking the wafer occurs simultaneously with, before, or after loading the wafer into the processing chamber. Step 1504 may include selecting a formation location of the exclusion area. It may be determined in advance where to form the exclusion area. In some embodiments, it may be determined where already-formed exclusion areas are located. The selection of the formation location of the exclusion area may be based on wafer alignment, scanning pattern, or properties relating to IC features formed on the other side of the wafer. At step 1506 a backside film is formed on the wafer according to a film formation process. At step 1508 the wafer is unloaded. At step 1510 an exclusion mask is removed from the wafer to reveal an exclusion area in the backside film. In some embodiments the step of unloading the wafer occurs simultaneously with, before, or after the step of removing the exclusion mask.

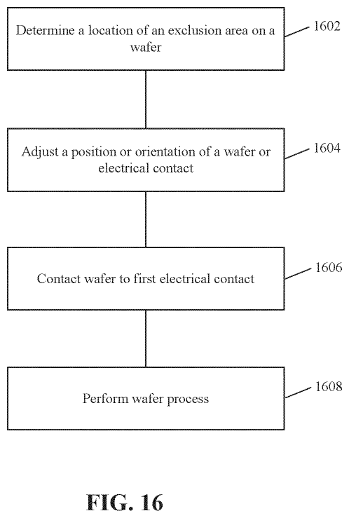

FIG. 16 illustrates a method 1600 for grounding a wafer held on a wafer holder, consistent with embodiments of the present disclosure. The wafer may have a coating on a surface of the wafer. The wafer holder may be part of, e.g., an electron beam tool as shown in FIG. 2, a wafer grounding system as shown in FIG. 3, or a wafer grounding subsystem as shown in FIGS. 6A-9B.

At step 1602, a location of an exclusion area of the coating is determined. Determining a location of the exclusion area may be based on information that is acquired during a determination process or information that is previously known. Information acquired during a determination process may include, e.g., optical or visual inspection information as discussed above. Information acquired during a determination process may include hardness testing, thickness measuring, or any measuring process that determines a property that relates to the wafer or exclusion area. In some embodiments, information acquired during a determination process may be based on an electrical inspection. For example, the electrical inspection may utilize sensor 316 to detect or measure electrical characteristic 320 as discussed above with respect to FIG. 3. Previously known information may include a location, shape, size or type of the exclusion area as provided by a manufacturer or supplier of the wafer. Previously known information may include a wafer map. Previously known information may comprise information acquired as discussed above, wherein the acquired information is acquired from a different wafer.

In some embodiments, step 1602 may include, e.g., detecting a reference feature and determining a location of exclusion areas based on a predetermined relationship between the reference feature and the exclusion area. For example, in step 1602 a pre-alignment detection system may be used to determine the position or orientation of an alignment notch or flat, a wafer edge, fiducial, or the reference feature. Alternatively or additionally, the reference feature may be determined by manual inspection by an operator.

In some embodiments, step 1602 may include, e.g., detecting a location of exclusion areas directly. For example, an exclusion area location may be determined by an optical inspection, a z-height sensor or other profilometer for identifying an exclusion area 613 by the wafer backside topography. The detection may be optical, capacitive, ultrasonic, or any other configuration for achieving the desired detection as discussed above.

At step 1604, a position or orientation of the wafer or a first electrical contact is adjusted so that the exclusion area is aligned with the first electrical contact. The first electrical contact may be a grounding pin. The adjustment may be performed before, during, or after loading the wafer onto a support. The position or orientation adjustment may be based on the determined location of the exclusion area in relation to the electrical contact. For example, a wafer may be rotated or translated so that an exclusion area is positioned above the first electrical contact. Alternatively, the first electrical contact may be actuated so that it is located below the exclusion area. The adjustment may include combined of movements of both the wafer and the first electrical contact.

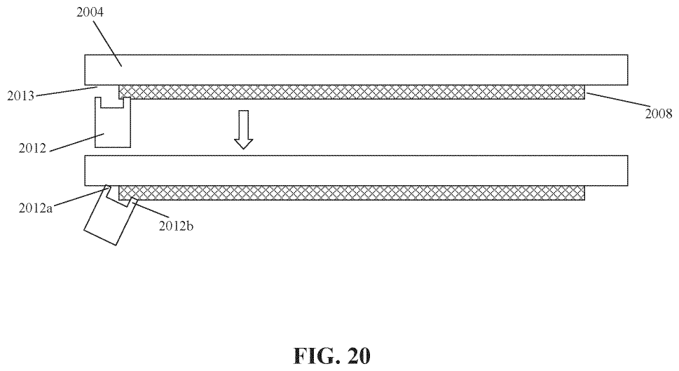

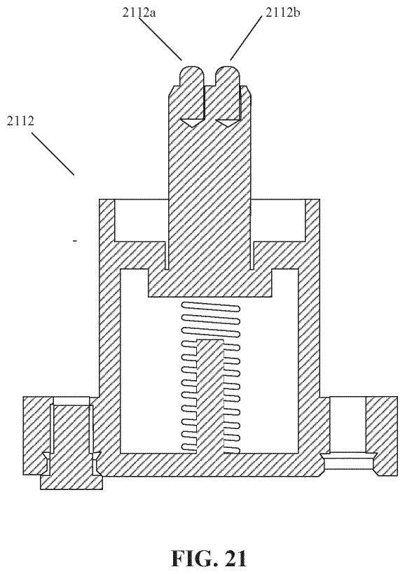

In some embodiments, to improve the position accuracy of the grounding pin contacting an exclusion area of the wafer, the grounding pin may include a pin body with two tips extending from the pin body (a “dual tip” grounding pin). A position of the dual tip grounding pin (e.g., dual tip grounding pin 2012 of FIG. 20, dual tip grounding pin 2112 of FIG. 21) may be flexibly adjusted such that the chance of the grounding pin contacting an exclusion area of the wafer increases.

At step 1606, the first electrical contact is contacted to the surface of the wafer. The first electrical contact may be actuated in the height direction so that the first electrical contact establishes sufficient electrical contact with the wafer to achieve a biasing or grounding operation. The contacting may include any of the exclusion grounding methods of the present disclosure, a penetration method, a zapping method, a pin-impact method, or any other suitable wafer grounding method or combinations of wafer grounding methods.

At step 1608, a charged particle beam process is performed while the wafer is biased or grounded. The charged particle beam may include wafer processing (e.g., e-beam direct write lithography system), process monitoring (e.g., critical dimension scanning electron microscope (CD-SEM)), wafer inspection (e.g., e-beam inspection system), defect analysis (e.g., defect review SEM, or DR-SEM and Focused Ion Beam system, or FIB), or any other wafer processing operation in which it is advantageous for the electrical properties of the wafer to be controlled.

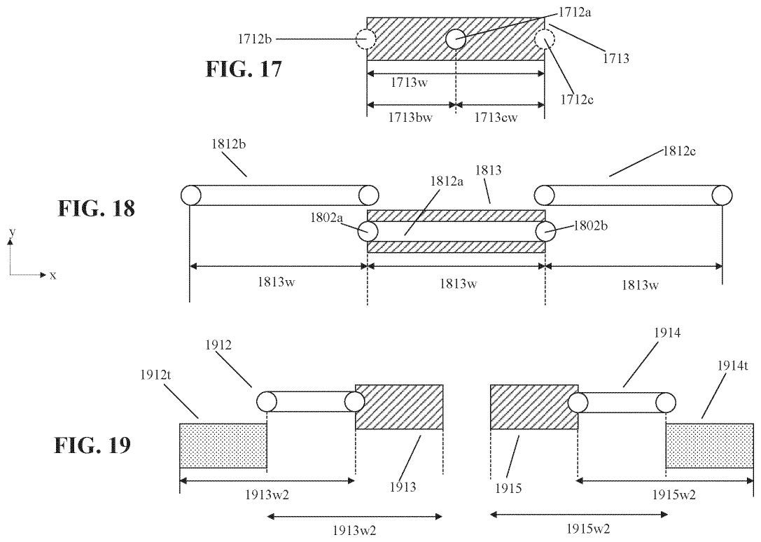

FIG. 17 shows an exemplary exclusion area 1713 of a wafer with positions of a single tip grounding pin. Exclusion area 1713 may be an area of a wafer without a backside film, thereby providing an area for grounding pins to easily make stable electrical contact with a conductive surface of the wafer. Exclusion area 1713 may have a width 1713w.

Typical grounding pins have a single tip that contacts the wafer or the backside film of the wafer. Because exclusion areas of a wafer may be small, the position accuracy of a single tip grounding pin contacting an exclusion area may be low. For example, a position 1712a of a single tip grounding pin may only be adjusted by half of width 1713w of exclusion area 1713. That is, if the single tip grounding pin is at position 1712a, the single tip grounding pin (or the wafer) may be adjusted by width 1713bw so that the grounding pin is at position 1712b or by width 1713cw so that the grounding pin is at position 1712c. Width 1713bw and width 1713cw may each be half of width 1713w. However, the position of the single tip grounding pin can only be adjusted to one of position 1712b or position 1712c, not both positions. That is, the location error tolerance of a single tip grounding pin may only be half of width 1713w.

Therefore, if the single tip grounding pin is positioned over a coated area (e.g., an area of the wafer with a backside film), the single tip grounding pin may not be able to be adjusted such that the single tip grounding pin contacts exclusion area 1713. Therefore, a single tip grounding pin may not be able to ground the wafer.

It is appreciated that while positions 1712a, 1712b, and 1712c and widths 1713w, 1713bw, and 1713c are depicted in FIG. 17, these elements may not actually be included on the wafer in practice.

FIG. 18 shows an exemplary exclusion area 1813 (e.g., exclusion areas 613 of FIGS. 6A-6C, inner exclusion area 613i of FIG. 6D, outer exclusion area 613o of FIG. 6D, exclusion area 713 of FIG. 7A, exclusion areas 813a-813b of FIG. 8A, exclusion areas 1013 of FIG. 10, exclusion areas 1213 of FIG. 12B, exclusion area 1413 of FIG. 14B, exclusion area 2013 of FIG. 20) of a wafer (e.g., wafer 203 of FIG. 2, wafer 304 of FIG. 3, wafer 404 of FIGS. 4A-4D, wafer 604 of FIGS. 6A-6D, wafer 704 of FIGS. 7A-7B, wafer 804 of FIGS. 8A-8B, wafer 904 of FIGS. 9A-9B, wafers (a)-(f) of FIG. 10, wafer 1204 of FIGS. 12A and 12C, wafer 1404 of FIG. 14A, wafer 2004 of FIG. 20) with positions of a dual tip grounding pin, consistent with some embodiments of the present disclosure. Exclusion area 1813 may have a width 1813w.

In some embodiments, to improve the position accuracy of grounding pins contacting an exclusion area of the wafer, each grounding pin may include a pin body with two tips extending from the pin body (a “dual tip” grounding pin). The distance between the first tip and the second tip of a grounding pin may be substantially equal to width 1813w of exclusion area 1813 (e.g., 0.01, 0.1, 0.5, 1, 1.5, 2, 3 or 5 mm or more) to improve the position accuracy of the grounding pin contacting exclusion area 1813 of the wafer. A position 1812a of a dual tip grounding pin may be flexibly adjusted such that the chance of the grounding pin contacting an exclusion area of the wafer increases (i.e., the dual tip grounding pin may increase position accuracy).

For example, a dual tip grounding pin may have a first tip at a position 1802a and a second tip at a position 1802b. Position 1812a of a dual tip grounding pin may be adjusted (e.g., linearly in an x or y direction) by width 1813a of exclusion area 1813 (e.g., by adjusting the dual tip grounding pin, the wafer, or any combination thereof). In some embodiments, position 1812a of the dual tip grounding pin or the wafer may be adjusted by rotating (e.g., in an angular direction parallel to or perpendicular to the surface of the wafer) the dual tip grounding pin. Therefore, if the dual tip grounding pin is at position 1812a, the dual tip grounding pin may be adjusted by width 1813w to position 1812b or adjusted by width 1813w to position 1812c. That is, the location error tolerance of a dual tip grounding pin may be twice the width 1813.

Therefore, if the dual tip grounding pin is positioned over a coated area (e.g., an area of the wafer with a backside film), the dual tip grounding pin or the wafer may be adjusted such that at least one tip of the dual tip grounding pin contacts exclusion area 1813 and grounds the wafer.

In some embodiments, a width of an exclusion area may be along the circumference/perimeter of the wafer (i.e., the width may extend in the same direction as the circumference/perimeter of the wafer). In some embodiments, a width of an exclusion area may extend towards a center of the wafer or in any direction of the wafer. That is, the direction and orientation of the width of an exclusion area is not limited.

It is appreciated that while positions 1812a, 1812b, 1812c, 1802a, and 1802b and width 1813w are depicted in FIG. 18, these elements may not actually be included on the wafer in practice.

FIG. 19 shows exemplary exclusion areas 1913 and 1915 (e.g., exclusion areas 613 of FIGS. 6A-6C, inner exclusion area 613i of FIG. 6D, outer exclusion area 613o of FIG. 6D, exclusion area 713 of FIG. 7A, exclusion areas 813a-813b of FIG. 8A, exclusion areas 1013 of FIG. 10, exclusion areas 1213 of FIG. 12B, exclusion area 1413 of FIG. 14B) of a wafer (e.g., wafer 203 of FIG. 2, wafer 304 of FIG. 3, wafer 404 of FIGS. 4A-4D, wafer 604 of FIGS. 6A-6D, wafer 704 of FIGS. 7A-7B, wafer 804 of FIGS. 8A-8B, wafer 904 of FIGS. 9A-9B, wafers (a)-(f) of FIG. 10, wafer 1204 of FIGS. 12A and 12C, wafer 1404 of FIG. 14A) with positions of a dual tip grounding pin, consistent with some embodiments of the present disclosure.

In some embodiments, as described above, the distance between the first tip and the second tip of a dual tip grounding pin may be substantially equal to the width of an exclusion area (e.g., exclusion areas 1913 and 1915) to improve the position accuracy of the grounding pin contacting exclusion areas 1913 and 1915 of the wafer. A position 1912 of a dual tip grounding pin may be flexibly adjusted such that the chance of the grounding pin contacting an exclusion area of the wafer increases (i.e., the dual tip grounding pin may increase position accuracy).

For example, position 1912 of a dual tip grounding pin may be adjusted (e.g., linearly in an x or y direction) by a width of exclusion area 1913 (e.g., by adjusting the dual tip grounding pin, the wafer, or any combination thereof). In some embodiments, position 1912 of the dual tip grounding pin or the wafer may be adjusted by rotating (e.g., in an angular direction parallel to or perpendicular to the surface of the wafer) the dual tip grounding pin. Therefore, if the dual tip grounding pin is at position 1912, the dual tip grounding pin may be adjusted by the width of exclusion area 1913 to cover tolerance area 1912t or adjusted by the width of exclusion area 1913 to cover exclusion area 1913. That is, the location error tolerance of a dual tip grounding pin may be a width 1913w 2, which is twice the width of exclusion area 1913.

Similarly, position 1914 of a second dual tip grounding pin may be adjusted (e.g., linearly in an x or y direction) by a width of exclusion area 1915 (e.g., by adjusting the dual tip grounding pin, the wafer, or any combination thereof). In some embodiments, position 1914 of the dual tip grounding pin or the wafer may be adjusted by rotating (e.g., in an angular direction parallel to or perpendicular to the surface of the wafer) the dual tip grounding pin. Therefore, if the dual tip grounding pin is at position 1914, the dual tip grounding pin may be adjusted by the width of exclusion area 1915 to cover tolerance area 1914t or adjusted by the width of exclusion area 1915 to cover exclusion area 1915. That is, the location error tolerance of a dual tip grounding pin may be a width 1915w2, which is twice the width of exclusion area 1915.

In some embodiments, a width of an exclusion area may be along the circumference/perimeter of the wafer (i.e., the width may extend in the same direction as the circumference/perimeter of the wafer). In some embodiments, a width of an exclusion area may extend towards a center of the wafer or in any direction of the wafer. That is, the direction and orientation of the width of an exclusion area is not limited.

It is appreciated that while positions 1912 and 1914, tolerance areas 1912t and 1914t, and widths 1913w2 and 1915w2 are depicted in FIG. 19, these elements may not actually be included on the wafer in practice.

FIG. 20 shows an exemplary wafer 2004 (e.g., wafer 203 of FIG. 2, wafer 304 of FIG. 3, wafer 404 of FIGS. 4A-4D, wafer 604 of FIGS. 6A-6D, wafer 704 of FIGS. 7A-7B, wafer 804 of FIGS. 8A-8B, wafer 904 of FIGS. 9A-9B, wafers (a)-(f) of FIG. 10, wafer 1204 of FIGS. 12A and 12C, wafer 1404 of FIG. 14A) with backside film 2008 (backside film 308 of FIG. 3, backside film 408 of FIGS. 4A-4D, backside film 608 of FIGS. 6A-6C, backside film 708 of FIG. 7B, backside film 808 of FIG. 8B, backside film 908 of FIGS. 9A-9B, backside film 1208 of FIG. 12B, backside film 1408 of FIG. 14B) in contact with dual tip grounding pin 2012, consistent with some embodiments of the present disclosure. Dual tip grounding pin 2012 may include a first tip 2012a and a second tip 2012b, each extending from the body of dual tip grounding pin 2012.

In some embodiments, wafer 2004 may include exclusion areas 2013 (e.g., exclusion areas 613 of FIGS. 6A-6C, inner exclusion area 613i of FIG. 6D, outer exclusion area 613o of FIG. 6D, exclusion area 713 of FIG. 7A, exclusion areas 813a-813b of FIG. 8A, exclusion areas 1013 of FIG. 10, exclusion areas 1213 of FIG. 12B, exclusion area 1413 of FIG. 14B).

In some embodiments, as described above, the distance between first tip 2012a and second tip 2012b may be substantially equal to a width (e.g., 1813w of FIG. 18) of exclusion area 2013 to improve the position accuracy of dual tip grounding pin 2012 contacting exclusion area 2013 of wafer 2004. A position (e.g., position 1812a of FIG. 18, position 1912 of FIG. 19, position 1914 of FIG. 19) of dual tip grounding pin 2012 may be flexibly adjusted such that the chance of dual tip grounding pin 2012 contacting exclusion area 2013 of wafer 2004 increases (i.e., the dual tip grounding pin may increase position accuracy).

For example, as shown in view (a) of FIG. 20, second tip 2012b of dual tip grounding pin 2012 may contact backside film 2008. However, as shown in view (b) of FIG. 20, dual tip grounding pin 2012 may be flexibly tilted such that first tip 2012a of dual tip grounding pin 2012 may contact exclusion area 2013, thereby grounding wafer 2004.

While a single dual tip grounding pin 2012 is shown in FIG. 20, it should be understood that a plurality of dual tip grounding pins may be included, each dual tip grounding pin corresponding to an exclusion area 2013 of wafer 2004.

In some embodiments, a width of an exclusion area may be along the circumference/perimeter of the wafer (i.e., the width may extend in the same direction as the circumference/perimeter of the wafer). In some embodiments, a width of an exclusion area may extend towards a center of the wafer or in any direction of the wafer. That is, the direction and orientation of the width of an exclusion area is not limited.

FIG. 21 shows a cross-sectional view of an exemplary dual tip grounding pin 2112 (e.g., dual tip grounding pin 2012 of FIG. 20), consistent with some embodiments of the present disclosure. Dual tip grounding pin 2112 may have a first tip 2112a (e.g., first tip 2012a of FIG. 20) and a second tip 2112b (e.g., second tip 2012b of FIG. 20), each extending from the body of dual tip grounding pin 2112.

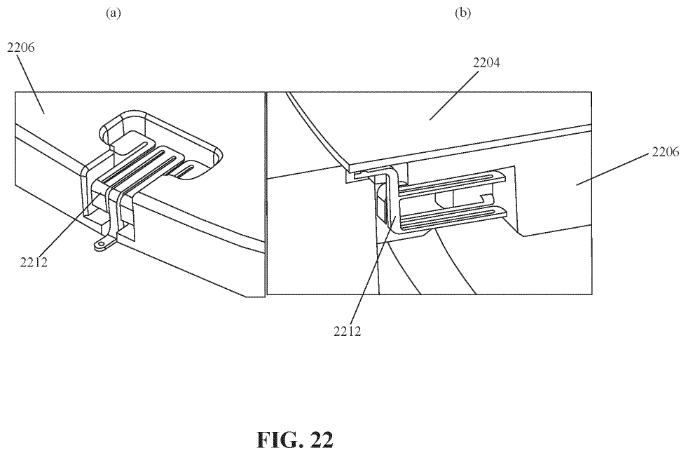

FIG. 22 shows an exemplary wafer holder 2206 (e.g., wafer holder 202 of FIG. 2, electrostatic holder 306 of FIG. 3, holder 706 of FIGS. 7A-7B, holder 806 of FIGS. 8A-8B, holder 906 of FIGS. 9A-9B) with a grounding pin 2212, consistent with some embodiments of the present disclosure. As shown in views (a) and (b) of FIG. 22, wafer holder 2206 may include grounding pin 2212, where grounding pin 2212 may include a spring structure. The spring structure of grounding pin 2212 may be configured to reduce wafer warp or wafer bow by reducing forces on wafer 2204 (e.g., wafer 203 of FIG. 2, wafer 304 of FIG. 3, wafer 404 of FIGS. 4A-4D, wafer 604 of FIGS. 6A-6D, wafer 704 of FIGS. 7A-7B, wafer 804 of FIGS. 8A-8B, wafer 904 of FIGS. 9A-9B, wafers (a)-(f) of FIG. 10, wafer 1204 of FIGS. 12A and 12C, wafer 1404 of FIG. 14A) with backside film 2008 (backside film 308 of FIG. 3, backside film 408 of FIGS. 4A-4D, backside film 608 of FIGS. 6A-6C, backside film 708 of FIG. 7B, backside film 808 of FIG. 8B, backside film 908 of FIGS. 9A-9B, backside film 1208 of FIG. 12B, backside film 1408 of FIG. 14B, wafer 2004 of FIG. 20). As shown in view (b) of FIG. 22, grounding pin 2212 may contact wafer 2204 at an exclusion area (e.g., exclusion areas 613 of FIGS. 6A-6C, inner exclusion area 613i of FIG. 6D, outer exclusion area 613o of FIG. 6D, exclusion area 713 of FIG. 7A, exclusion areas 813a-813b of FIG. 8A, exclusion areas 1013 of FIG. 10, exclusion areas 1213 of FIG. 12B, exclusion area 1413 of FIG. 14B, exclusion areas 2013 of FIG. 20) of wafer 2204 to ground wafer 2204.

While a single grounding pin 2212 is shown in FIG. 22, it should be understood that wafer holder 2206 may include a plurality of grounding pins, each grounding pin corresponding to an exclusion area of wafer 2204.

A non-transitory computer readable medium may be provided that stores instructions for a processor (for example, processor of controller 109 of FIG. 1) to carry out image processing, data processing, database management, graphical display, operations of a charged particle beam apparatus, or another imaging device, controlling wafer grounding, controlling wafer grounding location adjustment, implementing a pin-impact method, the example methods of FIGS. 15-16, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

The embodiments may further be described using the following clauses:
1. A method for electrically connecting to a wafer comprising:
contacting a first electrical contact to a surface of the wafer, the wafer having a coating on the surface;
wherein the contacting takes place at a first exclusion area of the coating.
2. The method of clause 1, further comprising:
determining a location of the first exclusion area; and
adjusting a position of the wafer or the first electrical contact so that the first exclusion area is aligned with the first electrical contact.
3. The method of clause 2, wherein adjusting the position of the wafer comprises:
translating a wafer holder that holds the wafer.
4. The method of clause 2, wherein adjusting the position of the wafer comprises:
rotating a wafer holder that holds the wafer.
5. The method of clause 2, wherein adjusting the position of the wafer comprises:
unloading the wafer from a first holding position in a wafer holder; and
reloading the wafer on the wafer holder in a second holding position different from the first holding position.
6. The method of clause 2, wherein adjusting the position of the wafer comprises:
unloading the wafer from a first holding orientation in a wafer holder; and
reloading the wafer on the wafer holder in a second holding orientation different from the first holding orientation.
7. The method of clause 2, wherein adjusting the position of the first electrical contact comprises: actuating the first electrical contact.
8. The method of clause 1, wherein the coating is a backside film configured to reduce a wafer warp or wafer bow.
9. The method of clause 1, wherein the exclusion area has a size of at least 1.5 mm in a radial direction of the surface.
10. The method of clause 1, wherein the exclusion area has a size that is at least twice the size of a cross-sectional contact area between the first electrical contact and the wafer.
11. The method of clause 1, wherein the wafer has a first electrical conductivity, the coating has a second electrical conductivity, and the first electrical conductivity is higher than the second electrical conductivity.
12. The method of clause 1, wherein the first exclusion area comprises a void in the coating that exposes an area on the surface of the wafer.
13. The method of clause 1, wherein the coating has a first thickness in the first exclusion area, a second thickness in an area adjacent to the first exclusion area, and the second thickness is greater than the first thickness.
14. The method of clause 1, wherein the coating has a thickness of at least 1 μm.
15. The method of clause 1, wherein the first exclusion area comprises a first material having a first electrical conductivity, the coating comprises a second material having a second electrical conductivity, and the first electrical conductivity is higher than the second electrical conductivity.
16. The method of clause 15, wherein the first material is substantially coplanar with the second material.
17. The method of clause 1, further comprising:
contacting a second electrical contact to the surface of the wafer,
wherein the first electrical contact and the second electrical contact are simultaneously in contact with the wafer.
18. The method of clause 17, wherein the second electrical contact is in contact with the wafer at a second exclusion area different from the first exclusion area.
19. The method of clause 17, wherein the first exclusion area comprises a first portion and a second portion, the method further comprising:
contacting the first electrical contact to the surface at the first portion, and
contacting the second electrical contact to the surface at the second portion.
20. The method of clause 19, wherein the first exclusion area has an annular shape.
21. The method of clause 1, wherein the first exclusion area has at least one of an annular shape, an arcuate shape, a rectangular shape, or a circular shape.
22. The method of clause 1, wherein the surface of the wafer comprises a second exclusion area different from the first exclusion area.
23. The method of clause 1, wherein the first exclusion area is located at a periphery of the surface.
24. The method of clause 1, further comprising:
separating the first electrical contact from the first exclusion area; and
contacting a second electrical contact to the first exclusion area, wherein the second electrical contact is different from the first electrical contact.
25. The method of clause 1, further comprising:
performing a charged particle beam process on the wafer;
wherein the first electrical contact is in contact with the surface of the wafer during the charged particle beam process.
26. The method of clause 25, wherein the charged particle beam process is a scanning electron microscope inspection of the wafer.
27. The method of clause 1, further comprising:
electrically connecting the wafer to a bias supply via the first electrical contact.
28. The method of clause 1, further comprising supplying a DC voltage to the wafer via the first electrical contact.
29. The method of clause 1, further comprising conducting electric charges away from the wafer by the first electrical contact.
30. The method of clause 29, wherein conducting the electric charges away from the wafer causes the wafer to become electrically neutral.
31. A non-transitory computer-readable medium storing a set of instructions that are executable by at least one processor of a device to cause the device to perform a method comprising:
contacting a first electrical contact to a surface of the wafer, the wafer having a coating on the surface;
wherein the contacting takes place at a first exclusion area of the coating.
32. The non-transitory computer-readable medium of clause 31, wherein the set of instructions that are executable by the at least one processor of the device causes the device to perform a method further comprising:
determining a location of the first exclusion area; and
adjusting a position of the wafer or the first electrical contact so that the first exclusion area is aligned with the first electrical contact.
33. The non-transitory computer-readable medium of clause 32, wherein adjusting the position of the wafer comprises:
translating a wafer holder that holds the wafer.
34. The non-transitory computer-readable medium of clause 32, wherein adjusting the position of the wafer comprises:
rotating a wafer holder that holds the wafer.
35. The non-transitory computer-readable medium of clause 32, wherein adjusting the position of the wafer comprises:
unloading the wafer from a first holding position in a wafer holder; and
reloading the wafer on the wafer holder in a second holding position different from the first holding position.
36. The non-transitory computer-readable medium of clause 32, wherein adjusting the position of the wafer comprises:
unloading the wafer from a first holding orientation in a wafer holder; and
reloading the wafer on the wafer holder in a second holding orientation different from the first holding orientation.
37. The non-transitory computer-readable medium of clause 32, wherein adjusting the position of the first electrical contact comprises:
actuating the first electrical contact.
38. The non-transitory computer-readable medium of clause 31, wherein the coating is a backside film configured to reduce a wafer warp or wafer bow.
39. The non-transitory computer-readable medium of clause 31, wherein the exclusion area has a size of at least 1.5 mm in a radial direction of the surface.
40. The non-transitory computer-readable medium of clause 31, wherein the exclusion area has a size that is at least twice the size of a cross-sectional contact area between the first electrical contact and the wafer.
41. The non-transitory computer-readable medium of clause 31, wherein the wafer has a first electrical conductivity, the coating has a second electrical conductivity, and the first electrical conductivity is higher than the second electrical conductivity.
42. The non-transitory computer-readable medium of clause 31, wherein the first exclusion area comprises a void in the coating that exposes an area on the surface of the wafer.
43. The non-transitory computer-readable medium of clause 31, wherein the coating has a first thickness in the first exclusion area, a second thickness in an area adjacent to the first exclusion area, and the second thickness is greater than the first thickness.
44. The non-transitory computer-readable medium of clause 31, wherein the coating has a thickness of at least 1 μm.
45. The non-transitory computer-readable medium of clause 31, wherein the first exclusion area comprises a first material having a first electrical conductivity, the coating comprises a second material having a second electrical conductivity, and the first electrical conductivity is higher than the second electrical conductivity.
46. The non-transitory computer-readable medium of clause 45, wherein the first material is substantially coplanar with the second material.
47. The non-transitory computer-readable medium of clause 31, wherein the set of instructions that are executable by the at least one processor of the device causes the device to further perform:
contacting a second electrical contact to the surface of the wafer,
wherein the first electrical contact and the second electrical contact are simultaneously in contact with the wafer.
48. The non-transitory computer-readable medium of clause 47, wherein the second electrical contact is in contact with the wafer at a second exclusion area different from the first exclusion area.
49. The non-transitory computer-readable medium of clause 47, wherein the first exclusion area comprises a first portion and a second portion, the method further comprising:
contacting the first electrical contact to the surface at the first portion, and
contacting the second electrical contact to the surface at the second portion.
50. The non-transitory computer-readable medium of clause 49, wherein the first exclusion area has an annular shape.
51. The non-transitory computer-readable medium of clause 31, wherein the first exclusion area has at least one of an annular shape, an arcuate shape, a rectangular shape, or a circular shape.
52. The non-transitory computer-readable medium of clause 31, wherein the surface of the wafer comprises a second exclusion area different from the first exclusion area.
53. The non-transitory computer-readable medium of clause 31, wherein the first exclusion area is located at a periphery of the surface.
54. The non-transitory computer-readable medium of clause 31, wherein the set of instructions that are executable by the at least one processor of the device causes the device to further perform:
separating the first electrical contact from the first exclusion area; and
contacting a second electrical contact to the first exclusion area, wherein the second electrical contact is different from the first electrical contact.
55. The non-transitory computer-readable medium of clause 31, wherein the set of instructions that are executable by the at least one processor of the device causes the device to further perform:
performing a charged particle beam process on the wafer;
wherein the first electrical contact is in contact with the surface of the wafer during the charged particle beam process.
56. The non-transitory computer-readable medium of clause 55, wherein the charged particle beam process is a scanning electron microscope inspection of the wafer.
57. The non-transitory computer-readable medium of clause 31, wherein the set of instructions that are executable by the at least one processor of the device causes the device to further perform:
electrically connecting the wafer to a bias supply via the first electrical contact.
58. The non-transitory computer-readable medium of clause 31, wherein the set of instructions that are executable by the at least one processor of the device causes the device to further perform:
supplying a DC voltage to the wafer via the first electrical contact.
59. The non-transitory computer-readable medium of clause 31, wherein the set of instructions that are executable by the at least one processor of the device causes the device to further perform:
conducting electric charges away from the wafer by the first electrical contact.
60. The non-transitory computer-readable medium of clause 59, wherein conducting the electric charges away from the wafer causes the wafer to become electrically neutral.
61. A charged particle beam apparatus, comprising:
a wafer holder configured to hold a wafer having a coating on a surface of the wafer;
a first electrical contact;
a charged particle beam source configured to expose the wafer to a charged particle beam; and
a controller configured to cause the first electrical contact to contact the surface of the wafer at a first exclusion area of the coating.
62. The charged particle beam apparatus of clause 61, wherein the controller is further configured to:
determine a location of the first exclusion area; and
adjust a position of the wafer or the first electrical contact so that the first exclusion area is aligned with the first electrical contact.
63. The charged particle beam apparatus of clause 62, wherein adjusting the position of the wafer comprises:
translating the wafer holder.
64. The charged particle beam apparatus of clause 62, wherein adjusting the position of the wafer comprises:
rotating the wafer holder.
65. The charged particle beam apparatus of clause 62, wherein adjusting the position of the wafer comprises:
unloading the wafer from a first holding position in the wafer holder; and
reloading the wafer on the wafer holder in a second holding position different from the first holding position.
66. The charged particle beam apparatus of clause 62, wherein adjusting the position of the wafer comprises:
unloading the wafer from a first holding orientation in the wafer holder; and
reloading the wafer on the wafer holder in a second holding orientation different from the first holding orientation.
67. The charged particle beam apparatus of clause 62, wherein adjusting the position of the first electrical contact comprises:
actuating the first electrical contact.
68. The charged particle beam apparatus of clause 61, wherein the coating is a backside film configured to reduce a wafer warp or wafer bow.
69. The charged particle beam apparatus of clause 61, wherein the exclusion area has a size of at least 1.5 mm in a radial direction of the surface.
70. The charged particle beam apparatus of clause 61, wherein the exclusion area has a size that is at least twice the size of a cross-sectional contact area between the first electrical contact and the wafer.
71. The charged particle beam apparatus of clause 61, wherein the wafer has a first electrical conductivity, the coating has a second electrical conductivity, and the first electrical conductivity is higher than the second electrical conductivity.
72. The charged particle beam apparatus of clause 61, wherein the first exclusion area comprises a void in the coating that exposes an area on the surface of the wafer.
73. The charged particle beam apparatus of clause 61, wherein the coating has a first thickness in the first exclusion area, a second thickness in an area adjacent to the first exclusion area, and the second thickness is greater than the first thickness.
74. The charged particle beam apparatus of clause 61, wherein the coating has a thickness of at least 1 μm.
75. The charged particle beam apparatus of clause 61, wherein the first exclusion area comprises a first material having a first electrical conductivity, the coating comprises a second material having a second electrical conductivity, and the first electrical conductivity is higher than the second electrical conductivity.
76. The charged particle beam apparatus of clause 75, wherein the first material is substantially coplanar with the second material.
77. The charged particle beam apparatus of clause 61, wherein
the controller is further configured to cause a second electrical contact to contact the surface of the wafer; and
the first electrical contact and the second electrical contact are configured to simultaneously be in contact with the wafer.
78. The charged particle beam apparatus of clause 77, wherein the second electrical contact is configured to be in contact with the wafer at a second exclusion area different from the first exclusion area.
79. The charged particle beam apparatus of clause 77, wherein:
the first exclusion area comprises a first portion and a second portion;
the controller is further configured to:
cause the first electrical contact to contact the surface at the first portion, and
cause the second electrical contact to contact the surface at the second portion.
80. The charged particle beam apparatus of clause 79, wherein the first exclusion area has an annular shape.
81. The charged particle beam apparatus of clause 61, wherein the first exclusion area has at least one of an annular shape, an arcuate shape, a rectangular shape, or a circular shape.
82. The charged particle beam apparatus of clause 61, wherein the surface of the wafer comprises a second exclusion area different from the first exclusion area.
83. The charged particle beam apparatus of clause 61, wherein the first exclusion area is located at a periphery of the surface.
84. The charged particle beam apparatus of clause 61, wherein the controller is further configured to:
separate the first electrical contact from the first exclusion area; and
contact a second electrical contact to the first exclusion area, wherein the second electrical contact is different from the first electrical contact.
85. The charged particle beam apparatus of clause 61, wherein the controller is further configured to:
perform a charged particle beam process on the wafer;
wherein the first electrical contact is in contact with the surface of the wafer during the charged particle beam process.
86. The charged particle beam apparatus of clause 85, wherein the charged particle beam process is a scanning electron microscope inspection of the wafer.
87. The charged particle beam apparatus of clause 61, further comprising:
a wafer bias supply;
wherein the controller is further configured to electrically connect the wafer to a bias supply via the first electrical contact.
88. The charged particle beam apparatus of clause 61, wherein the controller is further configured to supply a DC voltage to the wafer via the first electrical contact.
89. The charged particle beam apparatus of clause 61, wherein the first electrical contact is configured to conduct electric charges away from the wafer.
90. The charged particle beam apparatus of clause 89, wherein conducting the electric charges away from the wafer causes the wafer to become electrically neutral.
91. A wafer holding mechanism of a wafer processing system, comprising:
a wafer holder configured to hold a wafer in a processing chamber, the processing chamber configured to form a coating on the wafer; and
a first exclusion mask configured to cover a first exclusion area of the wafer, wherein the first exclusion mask is configured to reduce or prevent film formation at the first exclusion area during a film formation process in the processing chamber.
92. The wafer holding mechanism of clause 91, wherein the first exclusion mask is a support member of the wafer holder, the support member being configured to support the wafer at the first exclusion area.
93. The wafer holding mechanism of clause 92, further comprising a second exclusion mask configured to cover a second exclusion area of the wafer.
94. The wafer holding mechanism of clause 93, wherein the second exclusion mask does not substantially support the wafer.
95. The wafer holding mechanism of clause 94, wherein the second exclusion mask is configured to contact the wafer at the second exclusion area without substantially supporting it.
96. The wafer holding mechanism of clause 94, wherein the second exclusion mask is configured to reduce or prevent film formation at the second exclusion area without contacting the wafer.
97. The wafer holding mechanism of clause 94, wherein the second exclusion mask comprises a removable film.
98. The wafer holding mechanism of clause 91, wherein the first exclusion mask is configured to contact the wafer at the first exclusion area without substantially supporting it.
99. The wafer holding mechanism of clause 91, wherein the first exclusion mask is configured to reduce or prevent film formation at the first exclusion area without contacting the wafer.
100. The wafer holding mechanism of clause 99, wherein the wafer holder comprises a support member configured to support the wafer at an area other than the first exclusion area.
101. The wafer holding mechanism of clause 91, wherein the first exclusion mask has a shape that corresponds to a shape of the first exclusion area.
102. The wafer holding mechanism of clause 91, wherein the wafer holder comprises a table configured to support the wafer from underneath.
103. The wafer holding mechanism of clause 102, wherein the first exclusion mask is configured to cover the first exclusion area from above the wafer.
104. The wafer holding mechanism of clause 91, wherein the first exclusion mask comprises a removeable film.
105. The wafer holding mechanism of clause 91, wherein the processing chamber is one of a chemical vapor deposition chamber, a physical vapor deposition chamber, an atomic layer deposition chamber, and a passivation chamber.
106. A semiconductor wafer, comprising:
a coating on a wafer surface; and
a first exclusion area in the coating, the first exclusion area configured to facilitate a connection between an electrical contact of a charged particle beam inspection device and the wafer.
107. The semiconductor wafer of clause 106, wherein the coating is a backside film configured to reduce a wafer warp or wafer bow.
108. The semiconductor wafer of clause 106, wherein the first exclusion area has a size of at least 1.5 mm in a radial direction of the surface.
109. The semiconductor wafer of clause 106, wherein the first exclusion area has a size that is at least twice the size of a cross-sectional contact area between the electrical contact and the wafer.
110. The semiconductor wafer of clause 106, wherein the wafer has a first electrical conductivity, the coating has a second electrical conductivity, and the first electrical conductivity is higher than the second electrical conductivity.
111. The semiconductor wafer of clause 106, wherein the first exclusion area comprises a void in the coating that exposes an area on the surface of the wafer.
112. The semiconductor wafer of clause 106, wherein the coating has a first thickness in the first exclusion area, a second thickness in an area adjacent to the first exclusion area, and the second thickness is greater than the first thickness.
113. The method of clause 106, wherein the coating has a thickness of at least 1 μm.
114. The semiconductor wafer of clause 106, wherein the first exclusion area comprises a first material having a first electrical conductivity, the coating comprises a second material having a second electrical conductivity, and the first electrical conductivity is higher than the second electrical conductivity.
115. The semiconductor wafer of clause 114, wherein the first material is substantially coplanar with the second material.
116. The semiconductor wafer of clause 106, wherein the first exclusion area has at least one of an annular shape, an arcuate shape, a rectangular shape, or a circular shape.
117. The semiconductor wafer of clause 106, wherein the surface of the wafer comprises a second exclusion area different from the first exclusion area.
118. The semiconductor wafer of clause 106, wherein the first exclusion area is located at a periphery of the surface.
119. A method for forming a coating on a wafer surface, comprising:
loading a wafer into a processing chamber;
masking a first exclusion area on the wafer surface with a first exclusion mask; and
performing a film formation process in the processing chamber;
wherein the first exclusion mask reduces or eliminates film formation in the first exclusion area.
120. The method of clause 119, further comprising:
holding the wafer by a wafer holder of the processing chamber.
121. The method of clause 120, wherein the first exclusion mask is a support member of the wafer holder, the support member being configured to support the wafer at the exclusion area.
122. The method of clause 121, further comprising:
masking a second exclusion area on the wafer surface with a second exclusion mask.
123. The method of clause 122, wherein the second exclusion mask does not substantially support the wafer.
124. The method of clause 122, wherein the second exclusion mask contacts the wafer at the second exclusion area without substantially supporting it.
125. The method of clause 122, wherein the second exclusion mask reduces or prevents film formation at the second exclusion area without contacting the wafer.
126. The method of clause 122, wherein the second exclusion mask comprises a removable film.
127. The method of clause 120, wherein the wafer holder comprises a support member configured to support the wafer at an area other than the first exclusion area.
128. The method of clause 120, wherein the wafer holder comprises a table configured to support the wafer from underneath.
129. The method of clause 119, wherein the first exclusion mask is configured to contact the wafer at the first exclusion area without substantially supporting it.
130. The method of clause 119, further comprising supporting the wafer by a support member,
wherein the support member is configured to support the wafer at an area other than the first exclusion area.
131. The method of clause 119, wherein the first exclusion mask is configured to reduce or prevent film formation at the first exclusion area without contacting the wafer.
132. The method of clause 131, further comprising supporting the wafer by a support member,
wherein the support member is configured to support the wafer at an area other than the first exclusion area.
133. The method of clause 119, wherein the first exclusion mask has a shape that corresponds to a shape of the first exclusion area.
134. The method of clause 119, wherein the first exclusion mask is configured to cover the first exclusion area from above the wafer.
135. The method of clause 119, wherein first exclusion mask comprises a removeable film.
136. The method of clause 119, wherein film formation process comprises one of: chemical vapor deposition, physical vapor deposition, atomic layer deposition, and passivation.
137. A non-transitory computer-readable medium storing a set of instructions that are executable by at least one processor of a device to cause the device to perform a method comprising:
loading a wafer into a processing chamber;
masking a first exclusion area on the wafer surface with a first exclusion mask; and
performing a film formation process in the processing chamber;
wherein the first exclusion mask reduces or eliminates film formation in the first exclusion area.
138. The non-transitory computer-readable medium of clause 137, wherein the set of instructions that are executable by the at least one processor of the device causes the device to further perform:
holding the wafer by a wafer holder of the processing chamber.
139. The non-transitory computer-readable medium of clause 138, wherein the first exclusion mask is a support member of the wafer holder, the support member being configured to support the wafer at the first exclusion area.
140. The non-transitory computer-readable medium of clause 139, wherein the set of instructions that are executable by the at least one processor of the device causes the device to further perform:
masking a second exclusion area on the wafer surface with a second exclusion mask.
141. The non-transitory computer-readable medium of clause 140, wherein the second exclusion mask does not substantially support the wafer.
142. The non-transitory computer-readable medium of clause 140, wherein the second exclusion mask contacts the wafer at the second exclusion area without substantially supporting it.
143. The non-transitory computer-readable medium of clause 140, wherein the second exclusion mask reduces or prevents film formation at the second exclusion area without contacting the wafer.
144. The non-transitory computer-readable medium of clause 140, wherein the second exclusion mask comprises a removable film
145. The non-transitory computer-readable medium of clause 138, wherein the wafer holder comprises a support member configured to support the wafer at an area other than the first exclusion area.
146. The non-transitory computer-readable medium of clause 138, wherein the wafer holder comprises a table configured to support the wafer from underneath.
147. The non-transitory computer-readable medium of clause 137, wherein the first exclusion mask is configured to contact the wafer at the first exclusion area without substantially supporting it.
148. The non-transitory computer-readable medium of clause 147, wherein the set of instructions that are executable by the at least one processor of the device causes the device to further perform:
supporting the wafer by a support member,
wherein the support member is configured to support the wafer at an area other than the first exclusion area.
149. The non-transitory computer-readable medium of clause 137, wherein the first exclusion mask is configured to reduce or prevent film formation at the first exclusion area without contacting the wafer.
150. The non-transitory computer-readable medium of clause 149, wherein the set of instructions that are executable by the at least one processor of the device causes the device to further perform:
supporting the wafer by a support member,
wherein the support member is configured to support the wafer at an area other than the first exclusion area.
151. The non-transitory computer-readable medium of clause 137, wherein the first exclusion mask has a shape that corresponds to a shape of the first exclusion area.
152. The non-transitory computer-readable medium of clause 137, wherein the first exclusion mask is configured to cover the first exclusion area from above the wafer.
153. The non-transitory computer-readable medium of clause 137, wherein first exclusion mask comprises a removeable film.
154. The non-transitory computer-readable medium of clause 137, wherein film formation process comprises one of: chemical vapor deposition, physical vapor deposition, atomic layer deposition, and passivation.
155. The method of clause 1, further comprising:
causing the first electrical contact to contact the surface of the wafer by actuating the first electrical contact in a height direction.
156. The method of clause 1, further comprising:
performing a wafer grounding process by one of a pressing method, a zapping method, or a pin impact method.
157. The method of clause 2, wherein determining a location of the first exclusion area comprises:
detecting a location of a reference feature of the wafer; and
determining a location of the first exclusion area based on the detected location of the reference feature.
158. The method of clause 157, wherein the reference feature is one of an alignment notch, a flat portion of a wafer edge, or a fiducial mark.
159. The method of clause 2, wherein determining a location of the first exclusion area comprises:
detecting a location of the exclusion area with a sensor.
160. The method of clause 159, wherein detecting the location comprises any of:
detecting an optical property of the surface of the wafer;
detecting a capacitive property of the surface of the wafer;
detecting an acoustic property of the surface of the wafer; or
detecting a topography of the surface of the wafer.
161. The method of clause 2, wherein adjusting a position of the wafer or the first electrical contact comprises actuating one of a wafer holder, a wafer stage, or a wafer lifter.
162. The method of clause 1, wherein the exclusion area has a first size in a first direction that is not more than 750 μm larger than a dimension of the first electrical contact in the first direction when the first electrical contact is in contact with the exclusion area.
163. The method of clause 162, wherein the exclusion area has a second size in a second direction that is larger than the first size, the second direction being substantially perpendicular to the first direction.
164. The non-transitory computer readable medium of clause 31, wherein the set of instructions that are executable by the at least one processor of the device causes the device to further perform:
causing the first electrical contact to contact the surface of the wafer by actuating the first electrical contact in a height direction.
165. The non-transitory computer readable medium of clause 31, wherein the set of instructions that are executable by the at least one processor of the device causes the device to further perform a wafer grounding process by one of a pressing method, a zapping method, or a pin impact method.
166. The non-transitory computer readable medium of clause 32, wherein determining a location of the first exclusion area comprises:
detecting a location of a reference feature of the wafer; and
determining a location of the first exclusion area based on the detected location of the reference feature.
167. The non-transitory computer readable medium of clause 166, wherein the reference feature is one of an alignment notch, a flat portion of a wafer edge, or a fiducial mark.
168. The non-transitory computer readable medium of clause 32, wherein determining a location of the first exclusion area comprises:
detecting a location of the exclusion area with a sensor.
169. The non-transitory computer readable medium of clause 168, wherein detecting the location comprises any of:
detecting an optical property of the surface of the wafer;
detecting a capacitive property of the surface of the wafer;
detecting an acoustic property of the surface of the wafer; or
detecting a topography of the surface of the wafer.
170. The non-transitory computer readable medium of clause 32, wherein adjusting a position of the wafer or the first electrical contact comprises actuating one of a wafer holder, a wafer stage, or a wafer lifter.
171. The non-transitory computer readable medium of clause 31, wherein the exclusion area has a first size in a first direction that is not more than 750 μm larger than a dimension of the first electrical contact in the first direction when the first electrical contact is in contact with the exclusion area.
172. The non-transitory computer readable medium of clause 171, wherein the exclusion area has a second size in a second direction that is larger than the first size, the second direction being substantially perpendicular to the first direction.
173. The charged particle beam apparatus of clause 61, wherein the controller is further configured to cause the first electrical contact to contact the surface of the wafer by actuating the first electrical contact in a height direction.
174. The charged particle beam apparatus of clause 61, wherein the controller is further configured to perform a wafer grounding process by one of a pressing method, a zapping method, or a pin impact method.
175. The charged particle beam apparatus of clause 62, wherein determining a location of the first exclusion area comprises:
detecting a location of a reference feature of the wafer; and
determining a location of the first exclusion area based on the detected location of the reference feature.
176. The charged particle beam apparatus of clause 175, wherein the reference feature is one of an alignment notch, a flat portion of a wafer edge, or a fiducial mark.
177. The charged particle beam apparatus of clause 62, wherein determining a location of the first exclusion area comprises:
detecting a location of the exclusion area with a sensor.
178. The charged particle beam apparatus of clause 177, wherein detecting the location comprises any of:
detecting an optical property of the surface of the wafer;
detecting a capacitive property of the surface of the wafer;
detecting an acoustic property of the surface of the wafer; or
detecting a topography of the surface of the wafer.
179. The charged particle beam apparatus of clause 62, wherein adjusting a position of the wafer or the first electrical contact comprises actuating one of a wafer holder, a wafer stage, or a wafer lifter.
180. The charged particle beam apparatus of clause 61, wherein the exclusion area has a first size in a first direction that is not more than 750 μm larger than a dimension of the first electrical contact in the first direction when the first electrical contact is in contact with the exclusion area.
181. The charged particle beam apparatus of clause 180, wherein the exclusion area has a second size in a second direction that is larger than the first size, the second direction being substantially perpendicular to the first direction.
182. The method of any one of clauses 1-30 or 155-163, wherein the first electrical contact comprises a pin body, a first tip, and a second tip, the first tip and the second tip each extending from the pin body.
183. The method of clause 182, wherein a distance between the first tip and the second tip is substantially equal to a width of the first exclusion area of the coating.
184. The method of clause 183, further comprising adjusting the pin body to contact a surface of the wafer within the width of the first exclusion area of the coating.
185. The method of clause 184, wherein adjusting the pin body comprises any one of adjusting the pin body in a linear direction, adjusting the pin body in an angular direction, or any combination thereof.
186. The method of any one of clauses 1-30 or 155-163, wherein the first electrical contact comprises a spring within a wafer holder.
187. The method of clause 186, wherein the spring is configured to reduce wafer warp or wafer bow.
188. The method of any one of clauses 1-30, 155-163, or 182-187, wherein the first electrical contact comprises a plurality of first electrical contacts and the first exclusion area comprises a plurality of first exclusion areas, each first electrical contact corresponding to a first exclusion area.
189. The non-transitory computer-readable medium of any one of clauses 31-60 or 164-172, wherein the first electrical contact comprises a pin body, a first tip, and a second tip, the first tip and the second tip each extending from the pin body.
190. The non-transitory computer-readable medium of clause 189, wherein a distance between the first tip and the second tip is substantially equal to a width of the first exclusion area of the coating.
191. The non-transitory computer-readable medium of clause 190, wherein the set of instructions that are executable by the at least one processor of the device causes the device to further perform adjusting the pin body to contact a surface of the wafer within the width of the first exclusion area of the coating.
192. The non-transitory computer-readable medium of clause 191, wherein adjusting the pin body comprises any one of adjusting the pin body in a linear direction, adjusting the pin body in an angular direction, or any combination thereof.
193. The non-transitory computer-readable medium of any one of clauses 31-60 or 164-172, wherein the first electrical contact comprises a spring within a wafer holder.
194. The non-transitory computer-readable medium of clause 193, wherein the spring is configured to reduce wafer warp or wafer bow.
195. The non-transitory computer-readable medium of any one of clauses 31-60, 164-172, or 189-194, wherein the first electrical contact comprises a plurality of first electrical contacts and the first exclusion area comprises a plurality of first exclusion areas, each first electrical contact corresponding to a first exclusion area.
196. The charged particle beam apparatus of any one of clauses 61-90 or 173-181, wherein the first electrical contact comprises a pin body, a first tip, and a second tip, the first tip and the second tip each extending from the pin body.
197. The charged particle beam apparatus of clause 196, wherein a distance between the first tip and the second tip is substantially equal to a width of the first exclusion area of the coating.
198. The charged particle beam apparatus of clause 197, wherein the controller is further configured to adjust the pin body to contact a surface of the wafer within the width of the first exclusion area of the coating.
199. The charged particle beam apparatus of clause 198, wherein adjusting the pin body comprises any one of adjusting the pin body in a linear direction, adjusting the pin body in an angular direction, or any combination thereof.
200. The charged particle beam apparatus of any one of clauses 61-90 or 173-181, wherein the first electrical contact comprises a spring within a wafer holder.
201. The charged particle beam apparatus of clause 200, wherein the spring is configured to reduce wafer warp or wafer bow.
202. The charged particle beam apparatus of clauses 61-90, 173-181, or 196-201, wherein the first electrical contact comprises a plurality of first electrical contacts and the first exclusion area comprises a plurality of first exclusion areas, each first electrical contact corresponding to a first exclusion area.
203. The wafer holding mechanism of any one of clauses 91-105, the wafer holder further comprising a spring configured to contact the first exclusion area of the wafer.
204. The wafer holding mechanism of clause 203, wherein the spring is configured to reduce wafer warp or wafer bow.
205. The semiconductor wafer of any one of clauses 106-118, wherein the electrical contact comprises a pin body, a first tip, and a second tip, the first tip and the second tip each extending from the pin body.
206. The semiconductor wafer of clause 205, wherein a distance between the first tip and the second tip is substantially equal to a width of the first exclusion area of the coating.
207. The semiconductor wafer of clause 206, wherein the controller is further configured to adjust the pin body to contact a surface of the wafer within the width of the first exclusion area of the coating.
208. The semiconductor wafer of clause 207, wherein adjusting the pin body comprises any one of adjusting the pin body in a linear direction, adjusting the pin body in an angular direction, or any combination thereof.
209. The semiconductor wafer of any one of clauses 106-118, wherein the electrical contact comprising a spring within a wafer holder.
210. The semiconductor wafer of clause 209, wherein the spring is configured to reduce wafer warp or wafer bow.
211. The semiconductor wafer of any one of clauses 106-118 or 205-210, wherein the electrical contact comprises a plurality of electrical contacts and the first exclusion area comprises a plurality of first exclusion areas, each electrical contact corresponding to a first exclusion area.
212. A method for electrically connecting to a wafer comprising:
contacting a pin body to a surface of the wafer,
the wafer having a coating on the surface, and
the pin body comprising a first tip and a second tip each extending from the pin body;
wherein the contacting takes place at a first exclusion area of the coating by any one of the first tip, the second tip, or any combination thereof.
213. A non-transitory computer-readable medium storing a set of instructions that are executable by at least one processor of a device to cause the device to perform a method comprising:
contacting a pin body to a surface of the wafer,
the wafer having a coating on the surface, and
the pin body comprising a first tip and a second tip each extending from the pin body;
wherein the contacting takes place at a first exclusion area of the coating by any one of the first tip, the second tip, or any combination thereof.
214. A charged particle beam apparatus, comprising:
a wafer holder configured to hold a wafer having a coating on a surface of the wafer;
a pin body, the pin body comprising a first tip and a second tip each extending from the pin body;
a charged particle beam source configured to expose the wafer to a charged particle beam; and
a controller configured to cause any one of the first tip, the second tip, or any combination thereof to contact the surface of the wafer at a first exclusion area of the coating.
215. A semiconductor wafer, comprising:
a coating on a wafer surface; and
a first exclusion area in the coating, the first exclusion area configured to facilitate a connection between any one of a first tip extending from a pin body, a second tip extending from the pin body, or any combination thereof of a charged particle beam inspection device and the wafer.

It will be appreciated that the embodiments of the present disclosure are not limited to the exact construction that has been described above and illustrated in the accompanying drawings, and that various modifications and changes may be made without departing from the scope thereof.

1. A charged particle beam apparatus, comprising:
a wafer holder configured to hold a wafer having a coating on a surface of the wafer;
a first electrical contact;
a charged particle beam source configured to expose the wafer to a charged particle beam; and
a controller configured to cause the first electrical contact to contact the surface of the wafer at a first exclusion area of the coating.

2. The charged particle beam apparatus of claim 1, wherein the controller is further configured to:
determine a location of the first exclusion area; and
adjust a position of the wafer or the first electrical contact so that the first exclusion area is aligned with the first electrical contact.

3. The charged particle beam apparatus of claim 2, wherein determining a location of the first exclusion area comprises:
detecting a location of a reference feature of the wafer; and
determining a location of the first exclusion area based on the detected location of the reference feature.

4. The charged particle beam apparatus of claim 1, wherein the first exclusion area has a size of at least 1.5 mm in a radial direction of the surface.

5. The charged particle beam apparatus of claim 1, wherein the wafer has a first electrical conductivity, the coating has a second electrical conductivity, and the first electrical conductivity is higher than the second electrical conductivity.

6. The charged particle beam apparatus of claim 1, wherein the first exclusion area comprises a void in the coating that exposes an area on the surface of the wafer.

7. The charged particle beam apparatus of claim 1, wherein the coating has a first thickness in the first exclusion area, a second thickness in an area adjacent to the first exclusion area, and the second thickness is greater than the first thickness.

8. The charged particle beam apparatus of claim 1, wherein the coating has a thickness of at least 1 μm.

9. The charged particle beam apparatus of claim 1, wherein the first exclusion area comprises a first material having a first electrical conductivity, the coating comprises a second material having a second electrical conductivity, and the first electrical conductivity is higher than the second electrical conductivity.

10. The charged particle beam apparatus of claim 1, wherein
the controller is further configured to cause a second electrical contact to contact the surface of the wafer; and
the first electrical contact and the second electrical contact are configured to simultaneously be in contact with the wafer.

11. The charged particle beam apparatus of claim 1, wherein the first exclusion area has at least one of an annular shape, an arcuate shape, a rectangular shape, or a circular shape.

12. The charged particle beam apparatus of claim 1, wherein the controller is further configured to:
perform a charged particle beam process on the wafer;
wherein the first electrical contact is in contact with the surface of the wafer during the charged particle beam process.

13. The charged particle beam apparatus of claim 1, further comprising:
a wafer bias supply;
wherein the controller is further configured to electrically connect the wafer to a bias supply via the first electrical contact.

14. A non-transitory computer-readable medium storing a set of instructions that are executable by at least one processor of a device to cause the device to perform a method comprising:
contacting a first electrical contact to a surface of a wafer, the wafer having a coating on the surface;
wherein the contacting takes place at a first exclusion area of the coating.

15. A method for forming a coating on a wafer surface, comprising:
loading a wafer into a processing chamber;
masking a first exclusion area on the wafer surface with a first exclusion mask; and
performing a film formation process in the processing chamber;
wherein the first exclusion mask reduces or eliminates film formation in the first exclusion area.

16. The method of claim 15, further comprising:
holding the wafer by a wafer holder of the processing chamber.

17. The method of claim 16, wherein the first exclusion mask is a support member of the wafer holder, the support member being configured to support the wafer at the first exclusion area.

18. The method of claim 17, further comprising:
masking a second exclusion area on the wafer surface with a second exclusion mask.

19. The method of claim 18, wherein the second exclusion mask does not substantially support the wafer.

20. The method of claim 18, wherein the second exclusion mask contacts the wafer at the second exclusion area without substantially supporting it.
